(19) United States
(12) Patent Application Publication
(10) Pub. No.: US 2025/0201560 A1
(43) Pub. Date: Jun. 19, 2025

(54) METHODS OF FABRICATING SEMICONDUCTOR DEVICES

(71) Applicant: Samsung Electronics Co., Ltd., Suwon-si (KR)

(72) Inventors: Byunghoon KIM, Suwon-si (KR); Taeseop Choi, Suwon-si (KR); Bok-Yeon WON, Suwon-si (KR); Jihyun HWANG, Suwon-si (KR); Junho KIM, Suwon-si (KR); Yongseok SUH, Suwon-si (KR); Yongseok LEE, Suwon-si (KR); Jungwoo LEE, Suwon-si (KR); Hogyu CHOI, Suwon-si (KR)

(21) Appl. No.: 18/748,168

(22) Filed: Jun. 20, 2024

(30) Foreign Application Priority Data
Dec. 19, 2023 (KR) 10-2023-0186042

(51) Int. Cl. H01L 21/033; H01L 21/027

(52) U.S. Cl. CPC H01L 21/0337; H01L 21/0271; H01L 21/0332

(57) ABSTRACT

A method of fabricating a semiconductor device comprises: providing a substrate including a cell region and a peripheral region; stacking first and second mask layers on the substrate; patterning the second mask layer to form a first mask pattern including line patterns, wherein the line patterns extend from the cell region into a portion of the peripheral region, removing the first mask pattern on the portion; forming a first spacer layer on an upper surface of the first mask layer and on sidewalls and an upper surface of the first mask pattern on the cell region; etching the first spacer layer to form second mask patterns on the sidewalls of the first mask pattern on the cell region; removing the first mask pattern on the cell region; forming a third mask pattern on the peripheral region; and patterning the first mask layer using the second and third mask patterns.

### CROSS-REFERENCE TO RELATED APPLICATIONS

This U.S. nonprovisional application claims priority under 35 U.S.C. § 119 to Korean Patent Application No. 10-2023-0186042 filed on Dec. 19, 2023 in the Korean Intellectual Property Office, the disclosures of which are hereby incorporated by reference in their entirety.

### BACKGROUND OF THE INVENTION

The present inventive concepts relate to methods of fabricating semiconductor devices and, more particularly, to methods of fabricating semiconductor devices in which double patterning is used.

As the design rule of semiconductor devices decreases, forming fine patterns may be useful in realizing highly integrated semiconductor devices. Double patterning technology (DPT) may be useful to form a fine pattern whose dimension is less than a minimum size that can be achieved by a (single) photolithography process.

Double patterning technology (DPT) may be generally classified into self-alignment double patterning (SADP) process and self-alignment reversed patterning (SARP) process. The SARP process may include operations of forming spacers on opposite sides of each pattern of a set of patterns, selectively removing the patterns, and patterning an underlying layer using the spacers as etch masks. The SADP process may include operations of forming spacers between patterns, removing patterns, and patterning an underlying layer using the patterns as an etch mask.

### SUMMARY OF THE INVENTION

Some embodiments of the present inventive concepts provide methods of fabricating semiconductor devices in which method inferior goods may be reduced.

According to some embodiments of the present inventive concepts, a method of fabricating a semiconductor device, the method comprising: providing a substrate that includes a cell region and a peripheral circuit region; sequentially stacking a first mask layer and a second mask layer on the substrate; patterning the second mask layer to form a first mask pattern that includes line patterns, wherein the first mask pattern includes a first portion on the cell region and a second portion on the peripheral circuit region, wherein each of the line patterns extends across the cell region in a horizontal direction that is parallel with an upper surface and/or a lower surface of the substrate, wherein each of the line patterns extends in the horizontal direction into a portion of the peripheral circuit region, and wherein the portion of the peripheral circuit region is adjacent the cell region; removing the second portion of the first mask pattern; forming a first spacer layer on an upper surface of the first mask layer and on sidewalls and an upper surface of the first portion of the first mask pattern; etching the first spacer layer by a first anisotropic etching process to form second mask patterns on the sidewalls of the first portion of the first mask pattern; removing the first portion of the first mask pattern; forming a third mask pattern on the peripheral circuit region; and patterning the first mask layer using the second mask patterns and the third mask pattern.

According to some embodiments of the present inventive concepts, a method of fabricating a semiconductor device, the method comprising: providing a substrate that includes a cell region and a peripheral circuit region; sequentially stacking a first mask layer and a second mask layer on the substrate; patterning the second mask layer to form a first mask pattern, wherein the first mask pattern includes a first portion on the cell region and a second portion on the peripheral circuit region; removing the second portion of the first mask pattern; forming second mask patterns on sidewalls of the first portion of the first mask pattern; removing the first portion of the first mask pattern; forming a third mask pattern on the peripheral circuit region; and patterning the first mask layer using the second mask patterns and the third mask pattern, wherein the third mask pattern includes a first material different from a second material of the first mask pattern.

According to some embodiments of the present inventive concepts, a method of fabricating a semiconductor device, the method comprising: providing a substrate that includes a cell region and a peripheral circuit region; sequentially stacking a first mask layer and a second mask layer on the substrate; patterning the second mask layer to form a first mask pattern that includes line patterns on the cell region and a block pattern on the peripheral circuit region, wherein the line patterns extend from the cell region onto the peripheral circuit region, wherein lower surfaces of the line patterns on the cell region exposes the first mask layer, and wherein lower surfaces of the line patterns on the peripheral circuit region exposes the second mask layer; forming a spacer layer on the first mask pattern; etching the spacer layer on the peripheral circuit region by an anisotropic etching process to expose an upper surface of the block pattern and an upper surface of a first portion of the line patterns on the peripheral circuit region; removing the first portion of the line patterns on the peripheral circuit region and the block pattern; removing the spacer layer; forming a plurality of second mask patterns on sidewalls of a second portion of the line patterns on the cell region; removing the second portion of the line patterns; forming a third mask pattern on the peripheral circuit region; and patterning the first mask layer using the second mask patterns and the third mask pattern.

### BRIEF DESCRIPTION OF DRAWINGS

FIGS. 1A, 2A, 3A, 4A, 5A, 6A, 7A, 8A, 9A, 10A, 11A, 12A, 13A, 14A, 15A, 16A, and 17A illustrate plan views showing a method of fabricating a semiconductor device according to some embodiments of the present inventive concepts.

FIGS. 1B, 2B, 3B, 4B, 5B, 6B, 7B, 8B, 9B, 10B, 11B, 12B, 13B, 14B, 15B, 16B, and 17B illustrate cross-sectional views taken along line A-A′ of FIGS. 1A, 2A, 3A, 4A, 5A, 6A, 7A, 8A, 9A, 10A, 11A, 12A, 13A, 14A, 15A, 16A, and 17A, respectively.

FIGS. 1C, 2C, 3C, 4C, 5C, 6C, 7C, 8C, 9C, 10C, 11C, 12C, 13C, 14C, 15C, 16C, and 17C illustrate cross-sectional views taken along line B-B′ of FIGS. 1A, 2A, 3A, 4A, 5A, 6A, 7A, 8A, 9A, 10A, 11A, 12A, 13A, 14A, 15A, 16A, and 17A, respectively.

FIGS. 1D, 2D, 3D, 4D, 5D, 6D, 7D, 8D, 9D, 10D, 11D, 12D, 13D, 14D, 15D, 16D, and 17D illustrate cross-sectional views taken along line C-C′ of FIGS. 1A, 2A, 3A, 4A, 5A, 6A, 7A, 8A, 9A, 10A, 11A, 12A, 13A, 14A, 15A, 16A, and 17A, respectively.

FIG. 18 illustrates a plan view showing a semiconductor device according to some embodiments of the present inventive concepts.

FIG. 19 illustrates a cross-sectional view showing a semiconductor device according to some embodiments of the present inventive concepts.

### DETAILED DESCRIPTION OF THE INVENTION

The following will now describe methods of fabricating semiconductor devices according to the present inventive concepts in conjunction with the accompanying drawings.

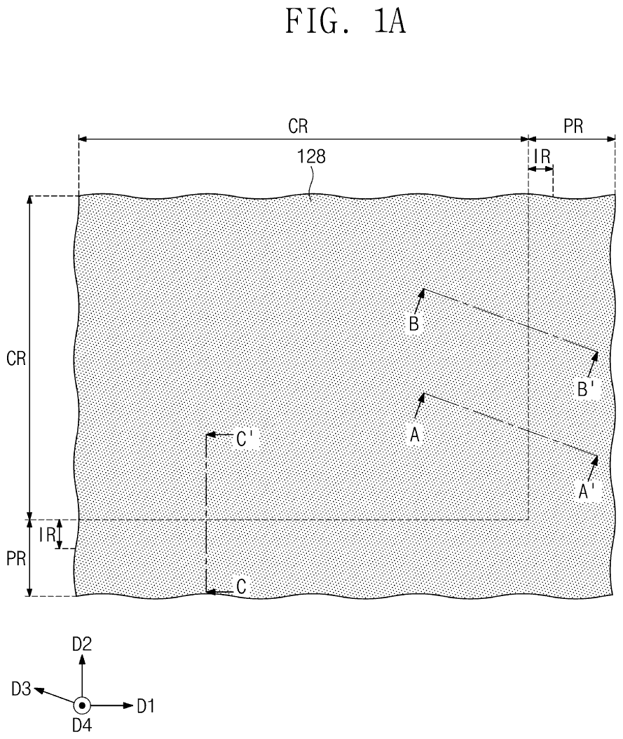

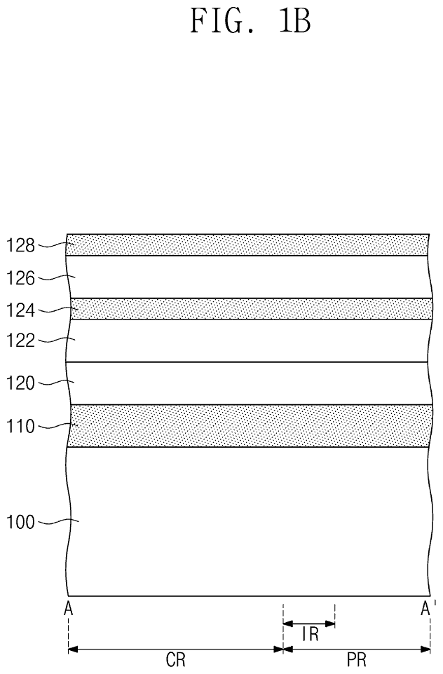

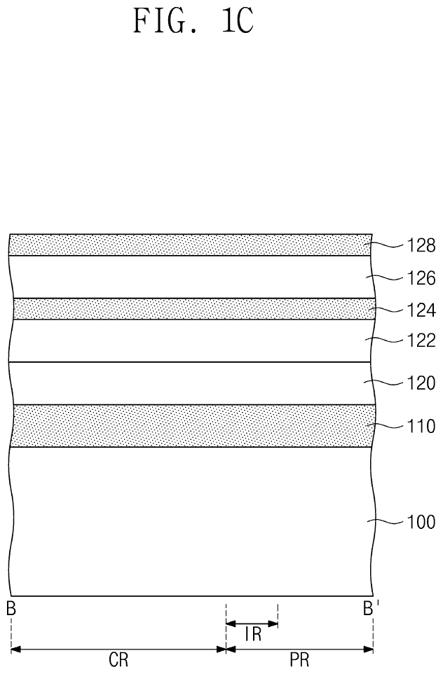

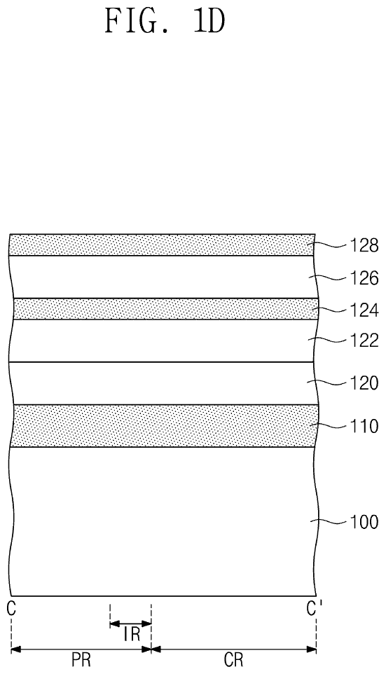

FIGS. 1A, 2A, 3A, 4A, 5A, 6A, 7A, 8A, 9A, 10A, 11A, 12A, 13A, and 14A illustrate plan views showing a method of fabricating a semiconductor device according to some embodiments of the present inventive concepts. FIGS. 1B, 2B, 3B, 4B, 5B, 6B, 7B, 8B, 9B, 10B, 11B, 12B, 13B, and 14B illustrate cross-sectional views taken along line A-A′ of FIGS. 1A, 2A, 3A, 4A, 5A, 6A, 7A, 8A, 9A, 10A, 11A, 12A, 13A, and 14A, respectively. FIGS. 1C, 2C, 3C, 4C, 5C, 6C, 7C, 8C, 9C, 10C, 11C, 12C, 13C, and 14C illustrate cross-sectional views taken along line B-B′ of FIGS. 1A, 2A, 3A, 4A, 5A, 6A, 7A, 8A, 9A, 10A, 11A, 12A, 13A, and 14A, respectively. FIGS. 1D, 2D, 3D, 4D, 5D, 6D, 7D, 8D, 9D, 10D, 11D, 12D, 13D, and 14D illustrate cross-sectional views taken along line C-C′ of FIGS. 1A, 2A, 3A, 4A, 5A, 6A, 7A, 8A, 9A, 10A, 11A, 12A, 13A, and 14A, respectively.

Referring to FIGS. 1A, 1B, 1C, and 1D, a dielectric layer 110, a semiconductor layer 120, a first mask layer 122, a first etch stop layer 124, a second mask layer 126, and a second etch stop layer 128 may be sequentially formed in a fourth direction D4 on a substrate 100. The fourth direction D4 may be perpendicular to (an upper surface and/or a lower surface of) the substrate 100.

The substrate 100 may include a cell region CR and a peripheral circuit region PR. The cell region CR may be a zone for forming memory cells. The peripheral circuit region PR may be a zone for forming a peripheral circuit to drive the memory cells. The substrate 100 may be a compound semiconductor substrate or a semiconductor substrate including, for example, silicon (Si), germanium (Ge), silicon-germanium (SiGe), and/or an epitaxial film obtained by performing selective epitaxial growth (SEG). For example, the substrate 100 may be a silicon (Si) substrate.

The dielectric layer 110 may include a material having an etch selectivity with respect to the substrate 100. The dielectric layer 110 may include, for example, a silicon oxide (SiOx) layer. The semiconductor layer 120 may include a semiconductor material, such as silicon (Si), germanium (Ge), and/or silicon-germanium (SiGe). In some embodiments, the semiconductor layer 120 may include an epitaxial film obtained by performing selective epitaxial growth (SEG). The substrate 100, the dielectric layer 110, and the semiconductor layer 120 may constitute a semiconductor-on-insulator structure in which a semiconductor layer is provided on a dielectric layer. For example, the substrate 100, the dielectric layer 110, and the semiconductor layer 120 may be a silicon-on-insulator (SOI) substrate, a germanium-on-insulator (GOI) substrate, or a silicon-on-sapphire (SOS) substrate.

The first mask layer 122 may be provided to prevent the semiconductor layer 120 from being damaged in subsequent processes where layers positioned on the first mask layer 122 are etched or patterned. The first mask layer 122 may include, for example, an amorphous carbon layer (ACL). The first etch stop layer 124 may include a material having an etch selectivity with respect to the first mask layer 122. The first etch stop layer 124 may include, for example, a silicon carbonitride (SiCN) layer and/or a silicon oxynitride (SiON) layer. The second mask layer 126 may include a material having an etch selectivity with respect to the first etch stop layer 124. The second mask layer 126 may include, for example, a spin-on-hardmask (SOH) layer. The second etch stop layer 128 may include a material having an etch selectivity with respect to the second mask layer 126. The second etch stop layer 128 may include, for example, a silicon oxynitride (SiON) layer.

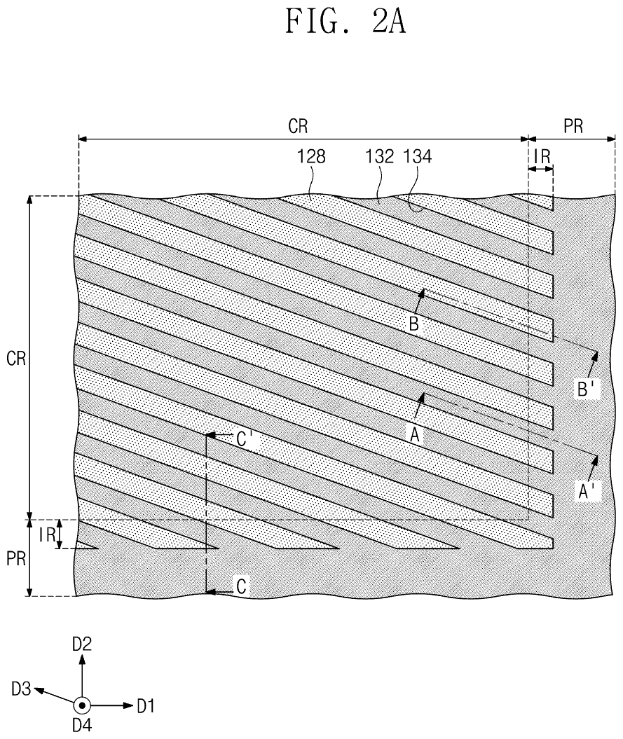

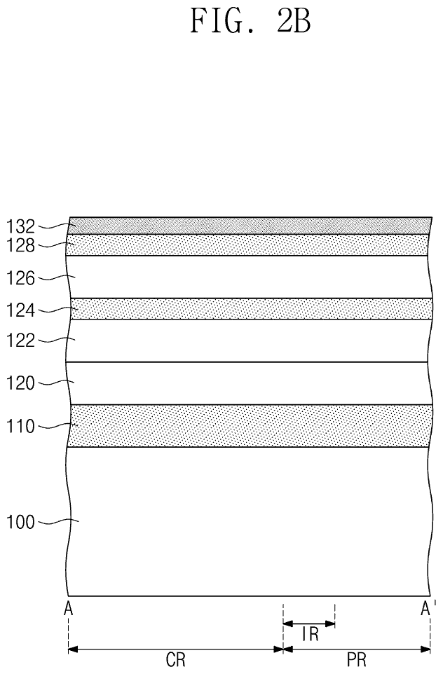

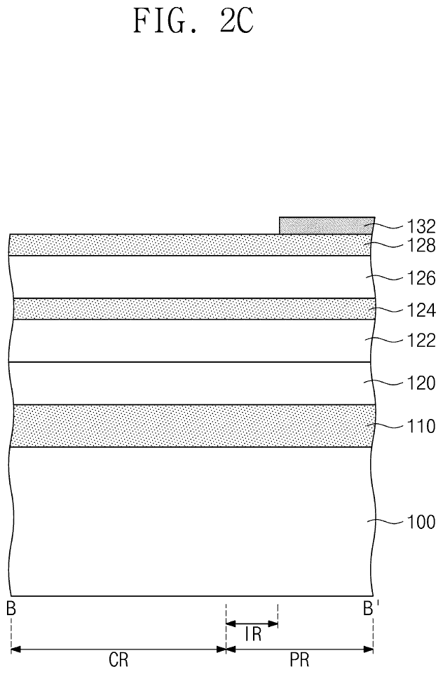

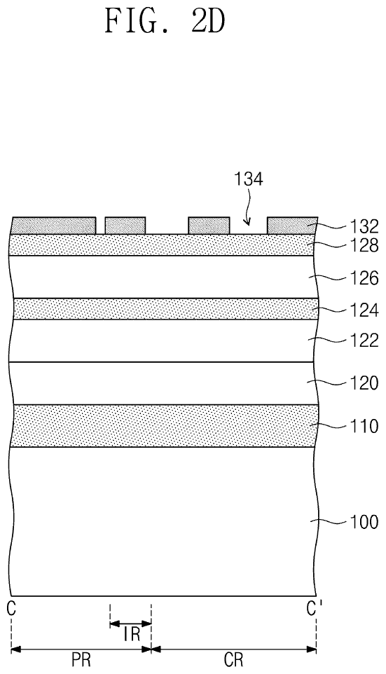

Referring to FIGS. 2A, 2B, 2C, and 2D, a first resist layer 132 may be formed on the second etch stop layer 128. The first resist layer 132 may include, for example, a photoresist material.

The first resist layer 132 may have openings 134. The openings 134 may be disposed on the cell region CR of the substrate 100. The openings 134 may partially expose the second etch stop layer 128 formed on the cell region CR of the substrate 100. For example, the openings 134 may have a linear shape that extends in a third direction D3 that intersects a first direction D1 and a second direction D2 that are orthogonal to each other. The first direction D1, the second direction D2, and the third direction D3 may be parallel with the upper surface and/or the lower surface of the substrate 100. The openings 134 may be spaced apart from each other, and may be arranged in a direction that intersects the third direction D3. On the cell region CR, the openings 134 may extend in the third direction D3 to reach the peripheral circuit region PR. For example, the openings 134 may have their ends positioned on an intermediate region IR on the peripheral circuit region PR. When viewed in plan, the intermediate region IR may extend around (e.g., at least partially surround) the cell region CR. The intermediate region IR may be adjacent (e.g., may be in contact with) the cell region CR. For example, the intermediate region IR may be a portion of the peripheral circuit region PR positioned adjacent to the cell region CR. The openings 134 may each have a width of (about) 2 nanometers to (about) 10 nanometers (in the direction that intersects the third direction D3). A remainder of the peripheral circuit region PR except the intermediate region IR may be covered (may be overlapped in the fourth direction D4) with the first resist layer 132. As used herein, “an element A overlapping an element B in a direction X” (or similar language) means that there is at least one line that extends in the direction X and intersects both the elements A and B.

According to some embodiments, before the first resist layer 132 is formed on the second etch stop layer 128, an antireflective coating layer may be formed on the second etch stop layer 128.

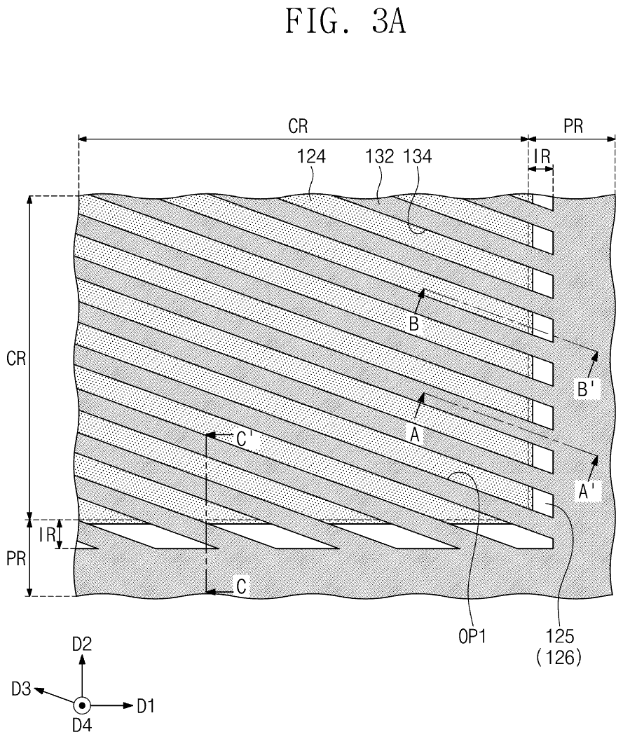

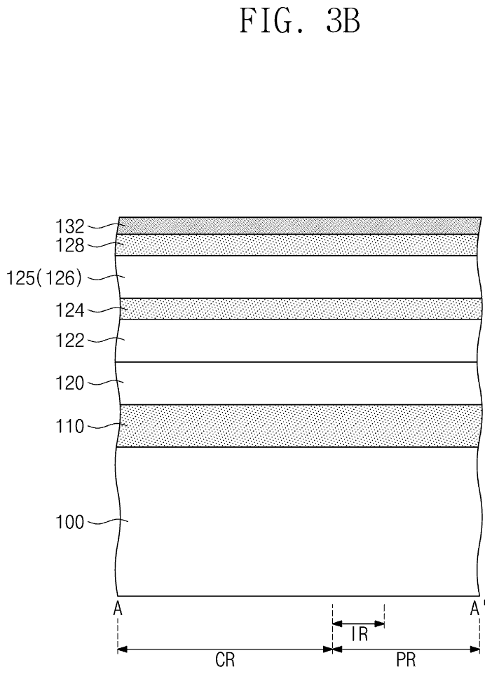

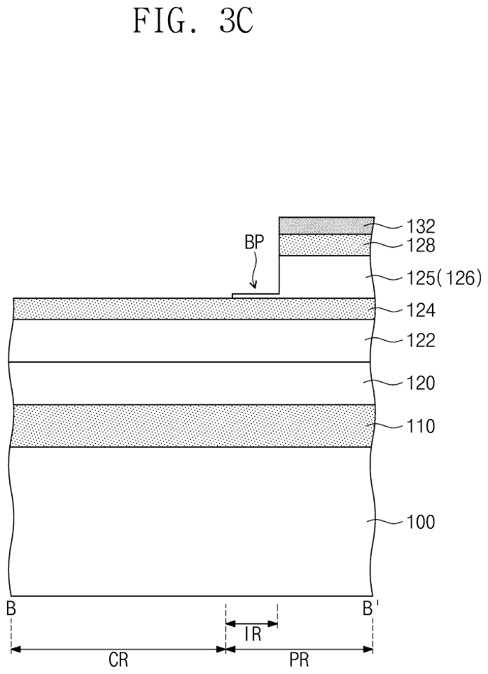

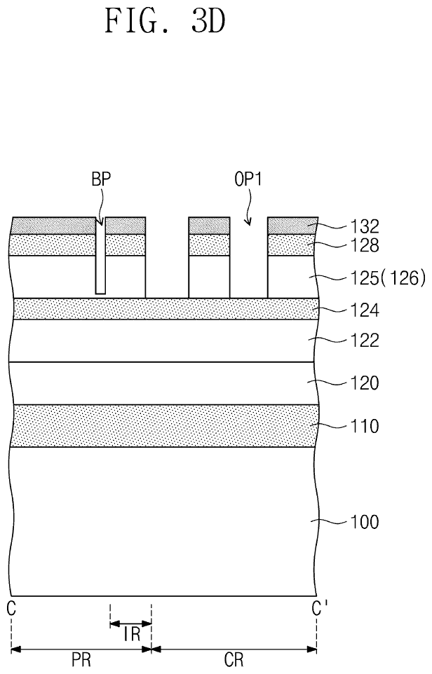

Referring to FIGS. 3A, 3B, 3C, and 3D, the first resist layer 132 may be used as an etch mask to (sequentially) etch the second etch stop layer 128, which is exposed by the openings 134, and the second mask layer 126. Therefore, first openings OP1 may be formed in the second etch stop layer 128 and the second mask layer 126.

The second mask layer 126 may be etched to form a first mask pattern 125. The first mask pattern 125 may include line patterns on the cell region CR and a first block pattern on the peripheral circuit region PR. The first block pattern may cover (may be overlapped in the fourth direction D4) a remainder of the peripheral circuit region PR except the intermediate region IR. For example, the remainder of the peripheral circuit region PR except the intermediate region IR may not be exposed by the first mask pattern 125. The line patterns may be portions of the first openings OP1 formed in the second mask layer 126. In the following description, the first openings OP1 and the line patterns will be allocated the same reference numeral ‘OP1’. For example, the line patterns OP1 may expose a portion of the first etch stop layer 124. In accordance with planar shapes of the openings 134, the line patterns OP1 may have their linear shapes that extend in the third direction D3. The line patterns OP1 may be spaced apart from each other and may be arranged in the direction that intersects the third direction D3. The line patterns OP1 may extend in the third direction D3 from the cell region CR to reach the peripheral circuit region PR. For example, the line patterns OP1 may have their ends positioned on the intermediate region IR on the peripheral circuit region PR. The line patterns OP1 may each have a width of (about) 2 nanometers to (about) 10 nanometers (in the direction that intersects the third direction D3). In some embodiments, the line patterns OP1 may entirely extend across the cell region CR.

As the openings 134 have their narrow widths, one or more of the line patterns OP1 or a portion of each of the line patterns OP1 may not completely penetrate (in the fourth direction D4) the second mask layer 126 in an etching process of the second etch stop layer 128 and the second mask layer 126. For example, portions of the ends of the line patterns OP1 in a lengthwise direction (e.g., the third direction D3) may not completely penetrate the second mask layer 126 (in the fourth direction D4). As the line patterns OP1 are formed on the cell region CR and the intermediate region IR, the ends of the line patterns OP1 may be positioned on the intermediate region IR. For example, on the intermediate region IR, the line patterns OP1 may expose the second mask layer 126, and on the cell region CR, the line patterns OP1 may expose the first etch stop layer 124. A bad pattern BP may refer to portions of the line patterns OP1 that do not completely penetrate the second mask layer 126 (in the fourth direction D4). In some embodiments, among the line patterns OP1 on the peripheral circuit region PR, portions other than the bad pattern BP or the line patterns OP1 that completely penetrate the second mask layer 126 may extend onto the intermediate region IR of the peripheral circuit region PR. In some embodiments, the line patterns OP1 may extend onto the intermediate region IR, and on the intermediate region IR, ends (e.g., some ends) of the line patterns OP1 may include the bad pattern BP.

According to some embodiments of the present inventive concepts, as the line patterns OP1 are formed to extend from the cell region CR onto the peripheral circuit region PR, the cell region CR may be provided thereon with portions of the line patterns OP1 that completely penetrate the second mask layer 126 (in the fourth direction D4). For example, the bad pattern BP may not be present on the cell region CR. There may thus be no occurrence of failure caused by insufficient exposure of a pattern on the cell region CR. This will be further discussed in detail below.

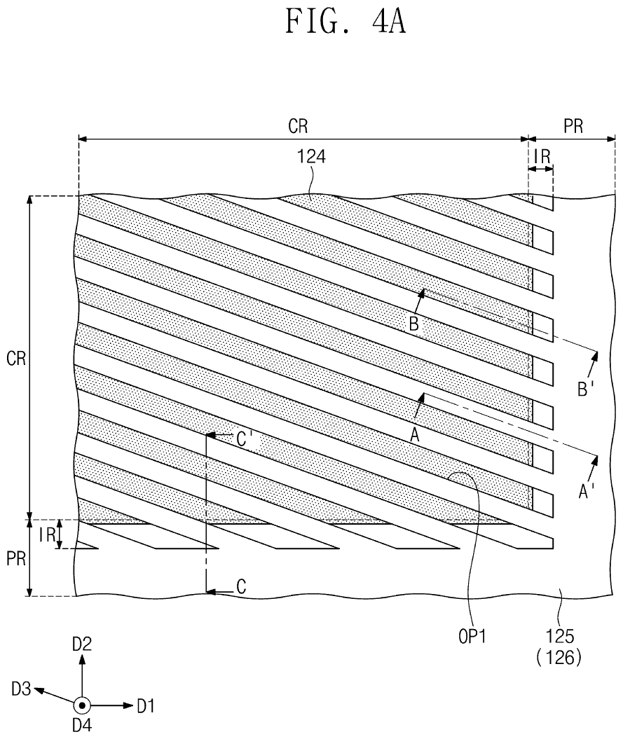

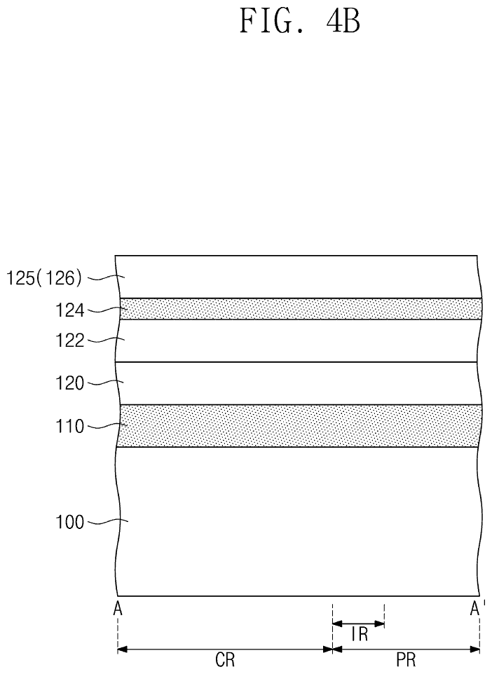

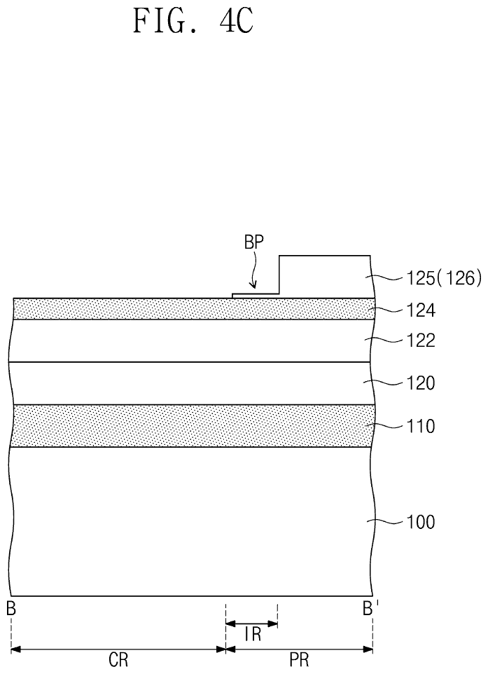

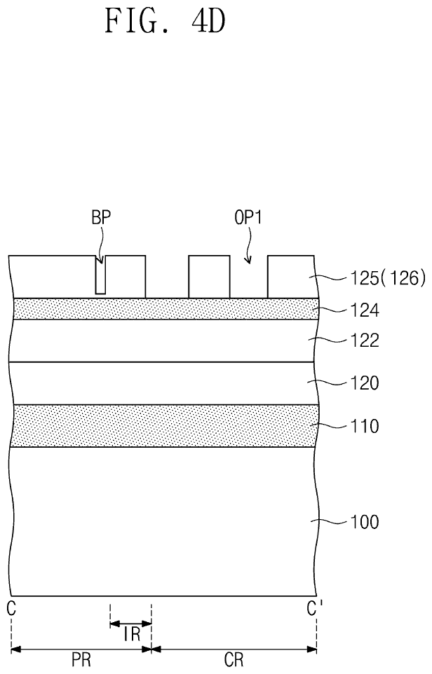

Referring to FIGS. 4A, 4B, 4C, and 4D, the first resist layer 132 and the second etch stop layer 128 may be (sequentially) removed. For example, an ashing or strip process may be performed to remove the first resist layer 132. For example, a wet etching process may be performed to remove the second etch stop layer 128. The first resist layer 132 and the second etch stop layer 128 may be removed to expose an upper surface of the first mask pattern 125.

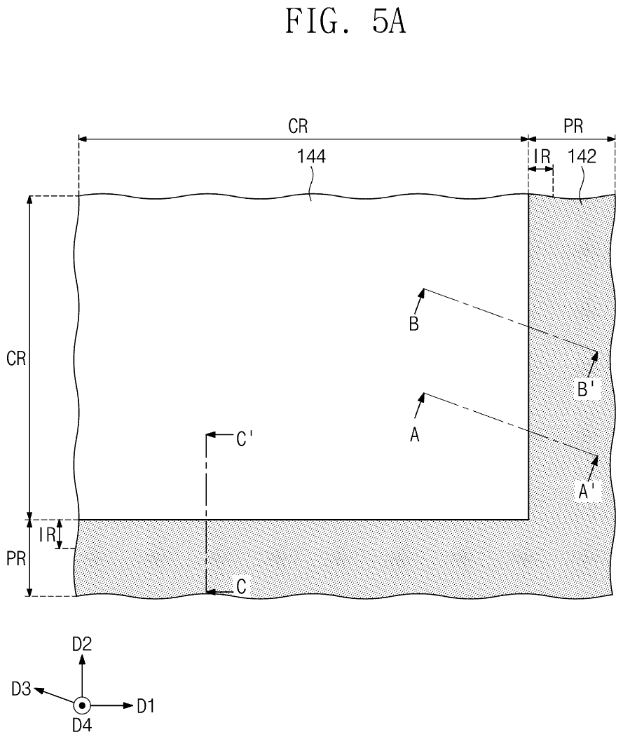

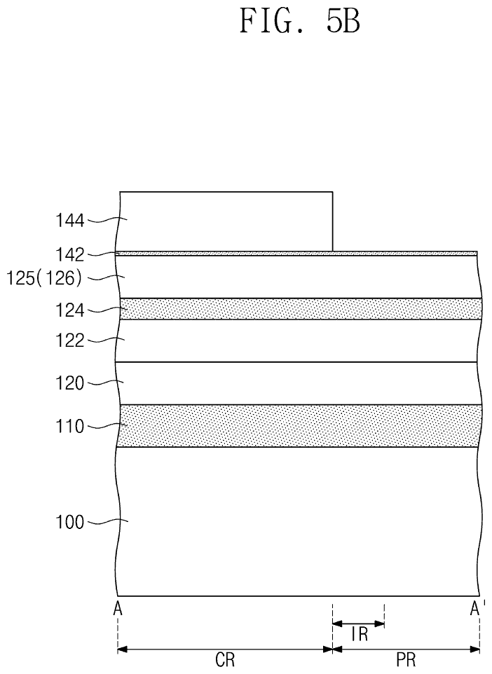

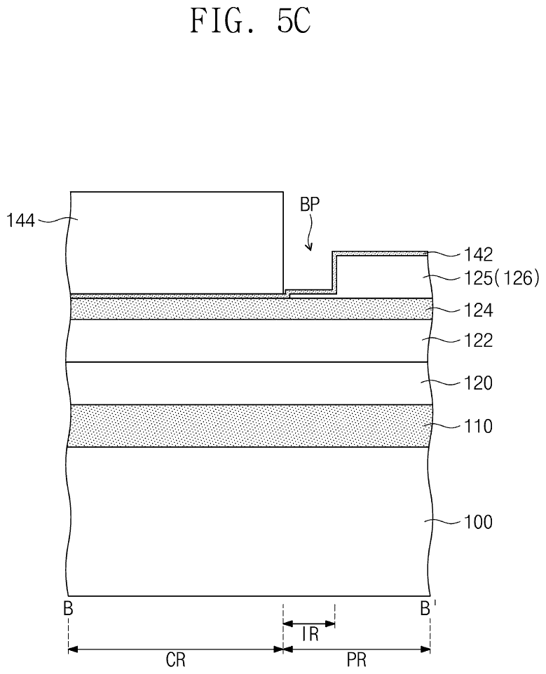

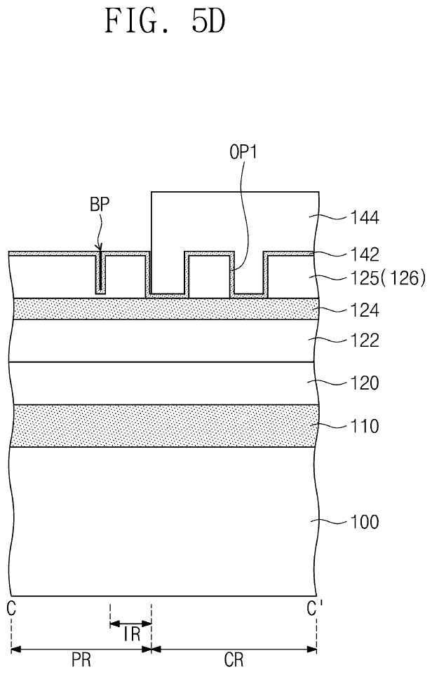

Referring to FIGS. 5A, 5B, 5C, and 5D, a first spacer layer 142 may be formed on the first etch stop layer 124. The first spacer layer 142 may be disposed on (e.g., may uniformly cover) the upper surface of the first mask pattern 125, sidewalls of the first mask pattern 125 that are exposed by the line patterns OP1, and an upper surface of the first etch stop layer 124 that is exposed by the line patterns OP1. In some embodiments, the first spacer layer 142 may be disposed on a sidewall of the first mask pattern 125 that is exposed by the bad pattern BP. The first spacer layer 142 may be disposed on a lower surface of the first mask pattern 125 that is exposed by the bad pattern BP. The first spacer layer 142 may be formed by, for example, atomic layer deposition (ALD). The first spacer layer 142 may include, for example, a silicon oxide (SiOx) layer.

A photomask pattern 144 may be formed on the first spacer layer 142. The photomask pattern 144 may include, for example, a photoresist material. The photomask pattern 144 may be on (e.g., may cover or overlap in the fourth direction D4) the cell region CR. The photomask pattern 144 may expose the peripheral circuit region PR. A portion of the first mask pattern 125 positioned on the peripheral circuit region PR may not be covered (may not be overlapped in the fourth direction D4) with the photomask pattern 144. In addition, the bad pattern BP positioned on the intermediate region IR of the peripheral circuit region PR may not be covered (may not be overlapped in the fourth direction D4) with the photomask pattern 144.

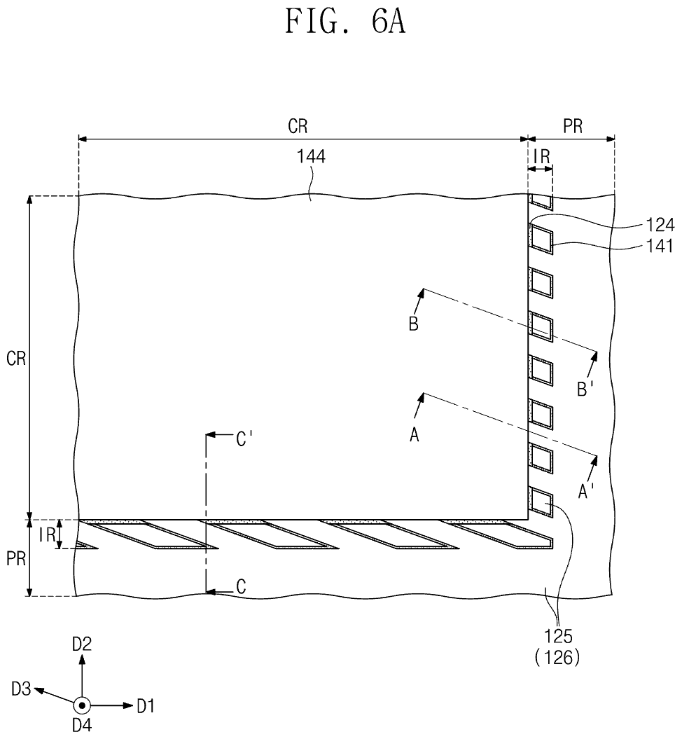

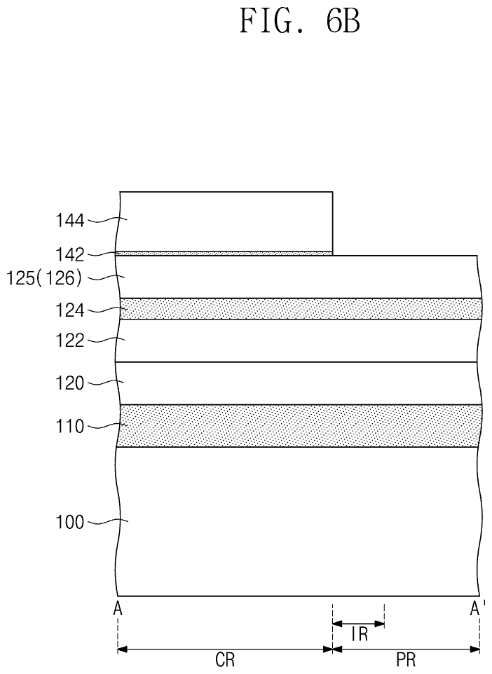

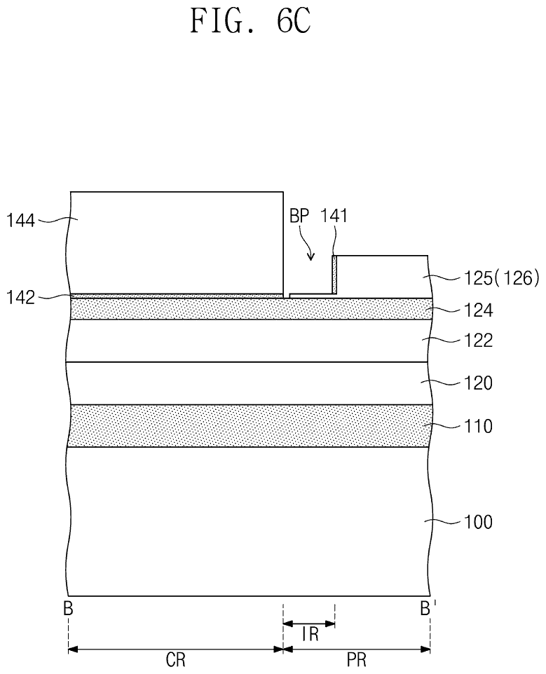

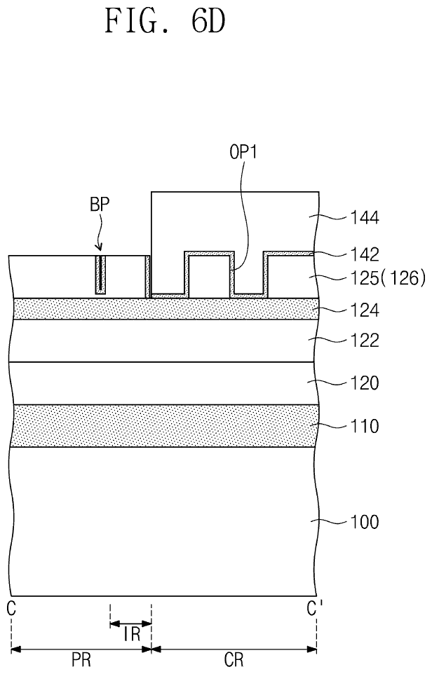

Referring to FIGS. 6A, 6B, 6C, and 6D, an etching process may be performed to etch a portion of the first spacer layer 142 that is on (e.g., covers or overlap in the fourth direction D4) the upper surface of the first etch stop layer 124 and the upper surface of the first mask pattern 125, thereby forming a second mask pattern 141. The etching process may continue until the upper surface of the first etch stop layer 124 is exposed and the upper surface of the first mask pattern 125 is exposed. In some embodiments, a portion of the first mask pattern 125 that corresponds to a lower surface of the bad pattern BP may be exposed. The etching process may include, for example, an anisotropic etching process. The photomask pattern 144 may not allow the etching process to perform on the cell region CR. Therefore, on the cell region CR, a portion of the first spacer layer 142 positioned below the photomask pattern 144 may remain. For example, the etching process may anisotropically etch a portion of the first spacer layer 142 on the peripheral circuit region PR to form the second mask pattern 141, but another portion of the first spacer layer 142 on the cell region CR may remain.

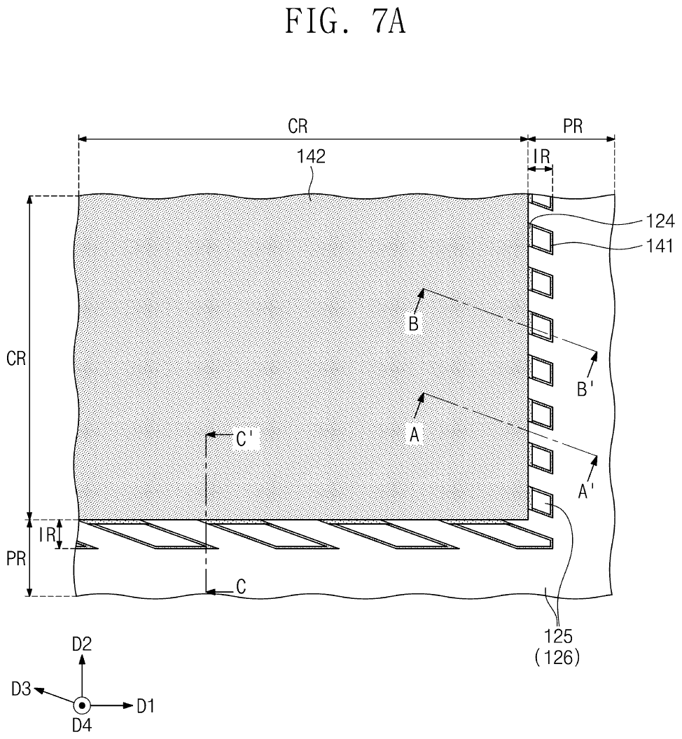

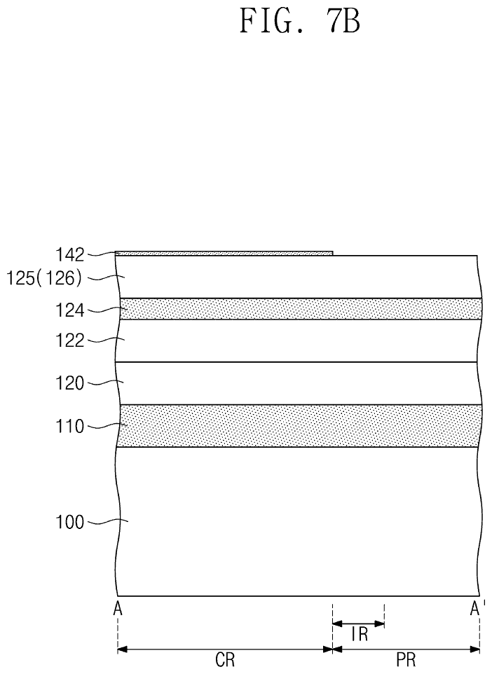

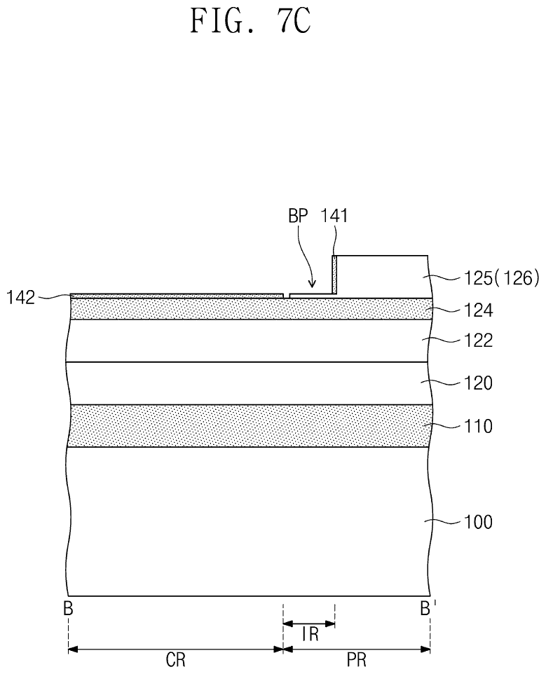

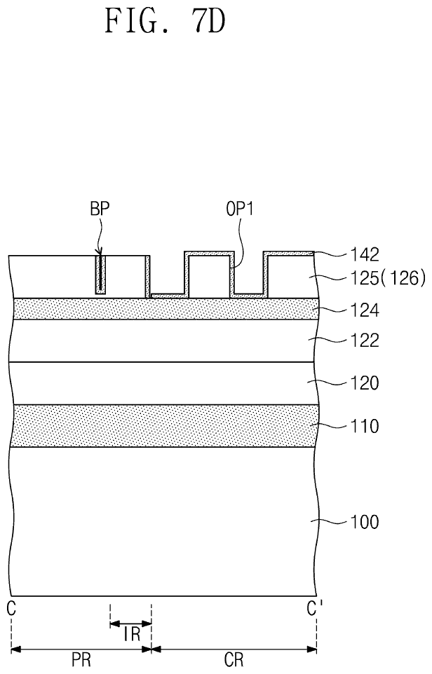

Referring to FIGS. 7A, 7B, 7C, and 7D, the photomask pattern 144 may be removed. An upper surface of the first spacer layer 142 positioned on the cell region CR, an upper surface of the second mask pattern 141 positioned on the peripheral circuit region PR, and an upper surface of the first mask pattern 125 positioned on the peripheral circuit region PR may be exposed. On the cell region CR, (the upper surface and the sidewalls of) the first mask pattern 125 may not be exposed but covered (overlapped) with the first spacer layer 142.

When a portion, other than the bad pattern BP, of the line patterns OP1 extends on the intermediate region IR, a portion of the top surface of the first etch stop layer 124 may also be exposed on the intermediate region IR.

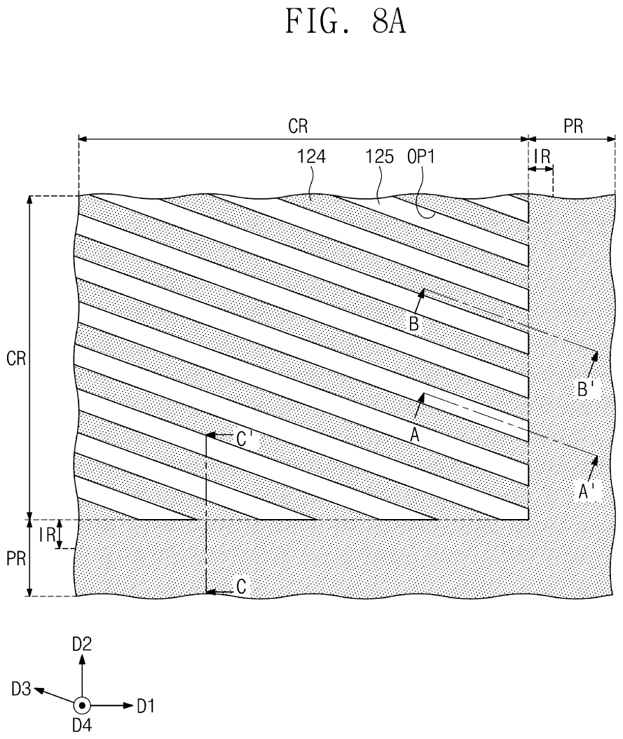

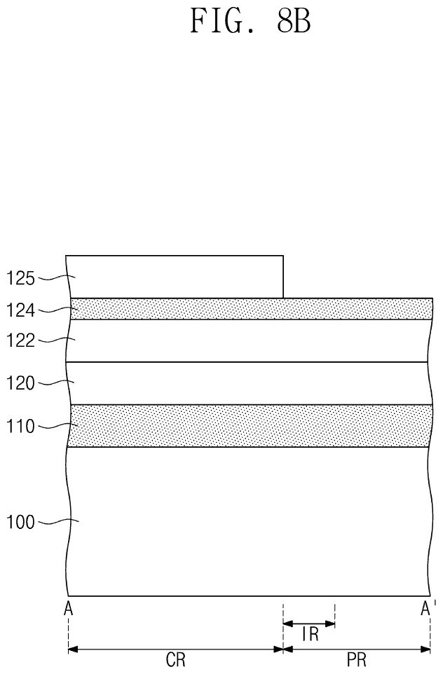

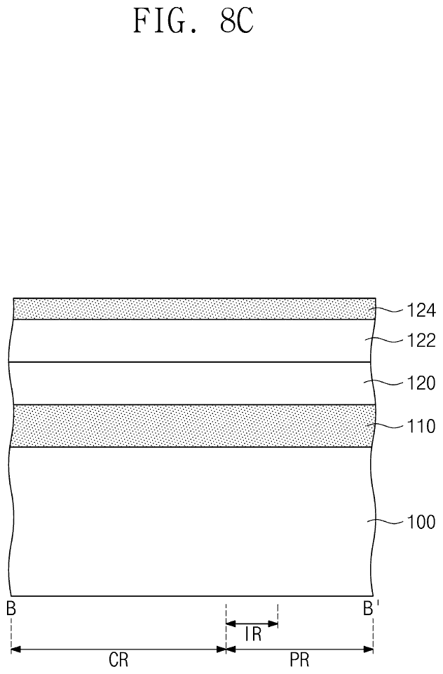

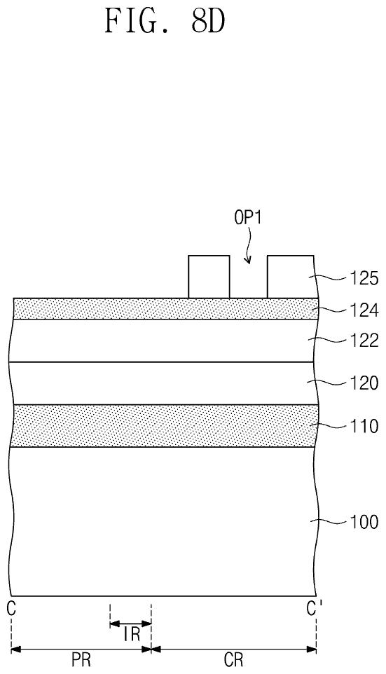

Referring to FIGS. 8A, 8B, 8C, and 8D, the first mask pattern 125 may be removed from the peripheral circuit region PR. On the peripheral circuit region PR, a portion of the first mask pattern 125 that is exposed without being covered with the second mask pattern 141 may be removed. For example, the first block pattern of the first mask pattern 125 positioned on the peripheral circuit region PR may be removed. In this step, the bad pattern BP positioned on the intermediate region IR may also be removed. The first mask pattern 125 positioned on the cell region CR may not be removed but protected by the first spacer layer 142. In this case, the cell region CR may be provided thereon with the first mask pattern 125 having normal (or good) line patterns OP1. For example, an ashing or strip process may be performed to remove a portion of the first mask pattern 125 (on the peripheral circuit region PR).

Afterwards, the second mask pattern 141 and the first spacer layer 142 may be removed. Thus, the upper surface of the first etch stop layer 124 and (the upper surface and the sidewalls of) the first mask pattern 125 positioned on the cell region CR may be exposed. For example, an ashing or strip process may be performed to remove the second mask pattern 141 and the first spacer layer 142. The process for removing the second mask pattern 141 and the first spacer layer 142 may be performed successively after or simultaneously with the process for removing the portion of the first mask pattern 125.

According to some embodiments of the present inventive concepts, on a zone larger than the cell region CR, the line patterns OP1 may be formed in the first mask pattern 125 so as to cover (or overlap) the cell region CR and a portion of the peripheral circuit region PR adjacent to the cell region CR (e.g., the intermediate region IR), and the first mask pattern 125 may be removed from the peripheral circuit region PR. Therefore, it may be possible to remove the bad pattern BP formed on ends or edges of the line patterns OP1 and to form the normally shaped line patterns OP1 on the cell region CR. There may thus be no occurrence of failure caused by insufficient exposure of the line patterns OP1 on the cell region CR. As a result, a method of fabricating a semiconductor device with less occurrence of failure may be provided.

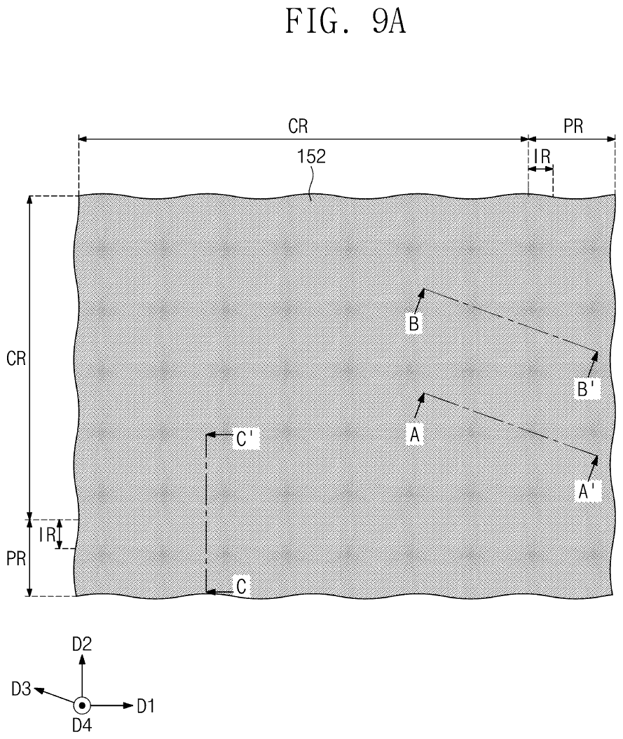

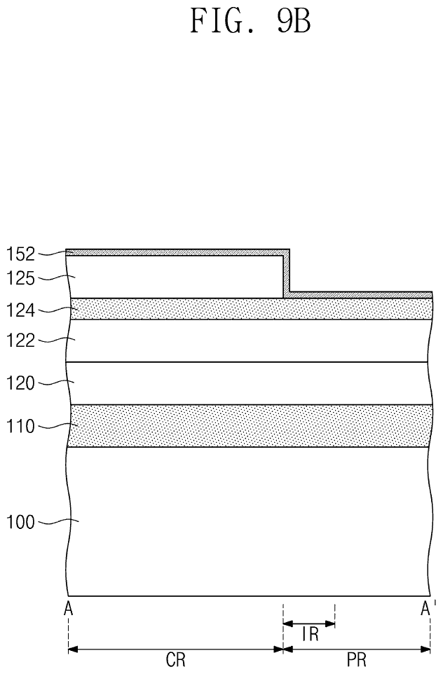

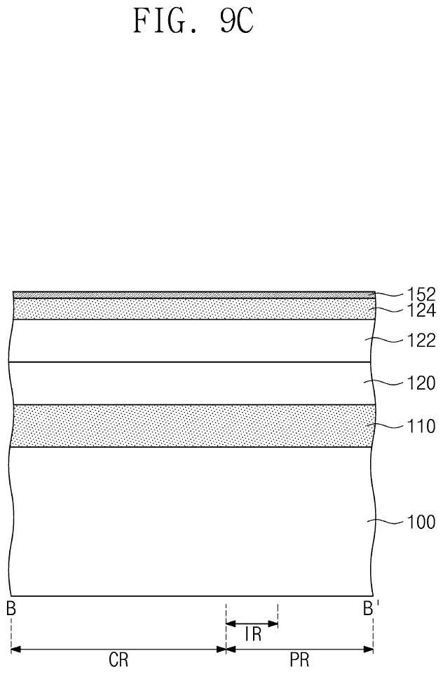

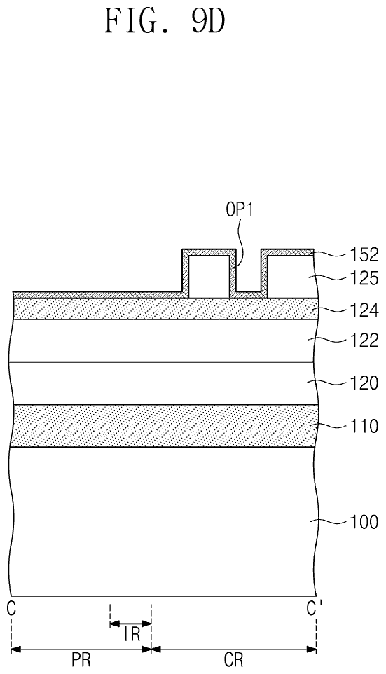

Referring to FIGS. 9A, 9B, 9C, and 9D, a second spacer layer 152 may be formed on the first etch stop layer 124. The second spacer layer 152 may be on (e.g., may uniformly cover) the upper surface of the first mask pattern 125, the sidewalls of the first mask pattern 125 that are exposed by the line patterns OP1, and the upper surface of the first etch stop layer 124 that is exposed by the line patterns OP1. The second spacer layer 152 may be formed by, for example, atomic layer deposition (ALD). The second spacer layer 152 may include, for example, a silicon oxide (SiOx) layer.

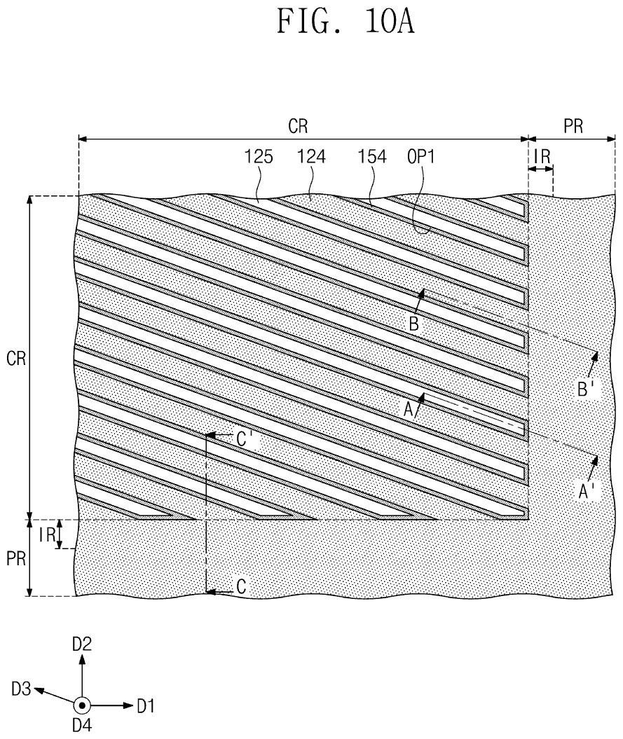

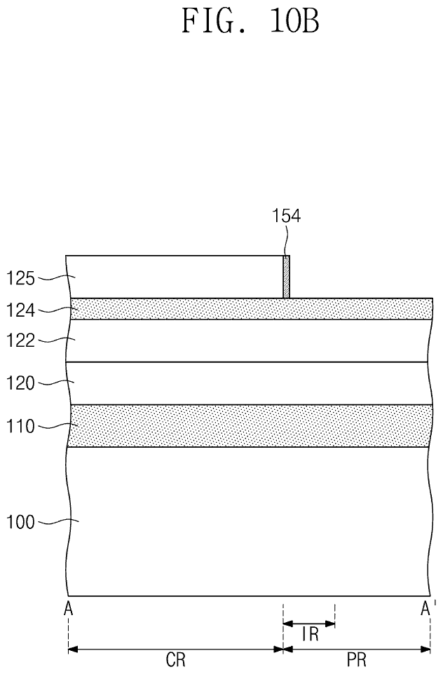

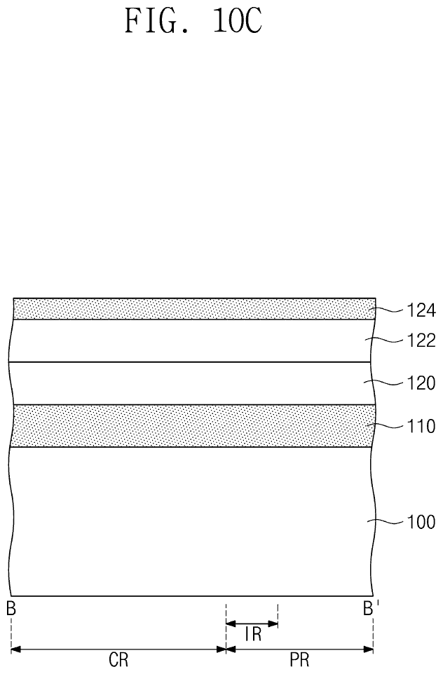

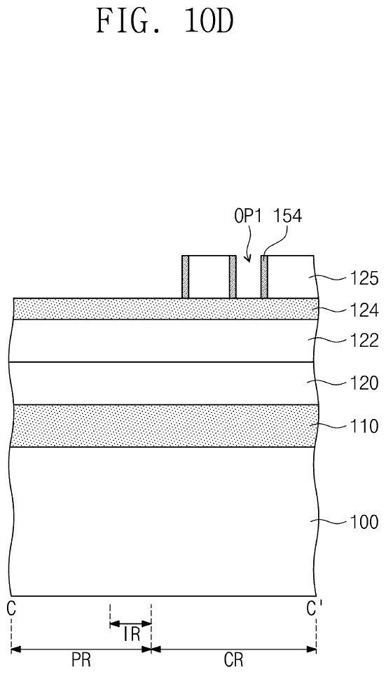

Referring to FIGS. 10A, 10B, 10C, and 10D, an etching process may be performed to etch a portion of the second spacer layer 152 that is on (e.g., covers or overlaps in the fourth direction D4) the upper surface of the first etch stop layer 124 and the upper surface of the first mask pattern 125, thereby forming a third mask pattern 154. The third mask pattern 154 may be a mask pattern for forming an active pattern on the semiconductor layer 120 in a subsequent process. The third mask pattern 154 may be formed in the line patterns OP1 of the first mask pattern 125. For example, the third mask pattern 154 may be on the sidewalls of the first mask pattern 125. The etching process may continue until the upper surface of the first etch stop layer 124 is exposed and the upper surface of the first mask pattern 125 is exposed. The third mask pattern 154 may be formed on the cell region CR and may not be formed on the peripheral circuit region PR.

Although not shown, during the etching process that etches a portion of the second spacer layer 152, an upper portion of the first etch stop layer 124 on the peripheral circuit region PR may also be partially etched. Therefore, the upper surface of the first etch stop layer 124 on the peripheral circuit region PR may be located at a lower level than that of the upper surface of the first etch stop layer 124 on the cell region CR. The following description will focus on the embodiment of FIGS. 10A, 10B, 10C, and 10D. The level (height or the like) may be a relative location (e.g., distance) from a substrate or other common element (e.g., the substrate 100) in a vertical direction (e.g., the fourth direction D4). A farther distance from the substrate may be a higher level. A closer distance from the substrate may be a lower level.

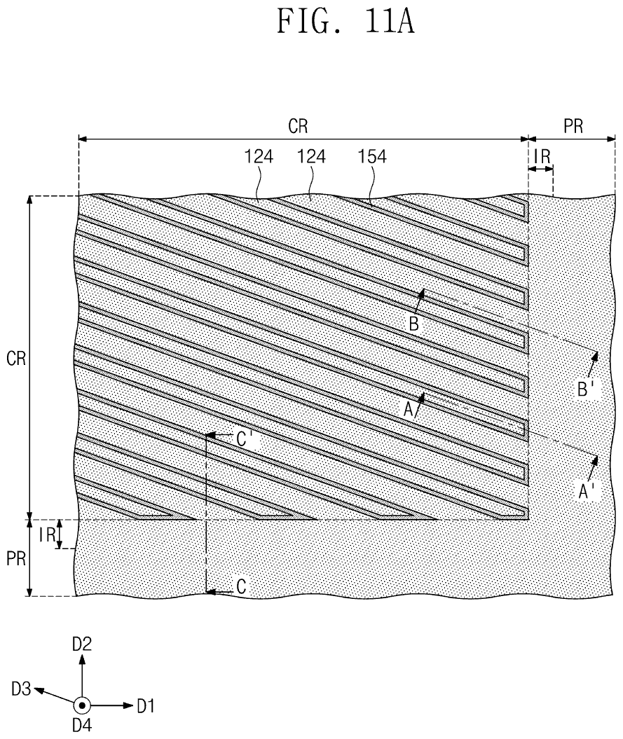

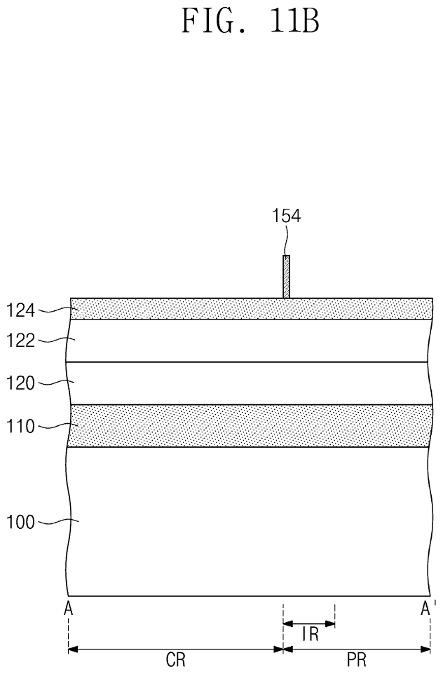

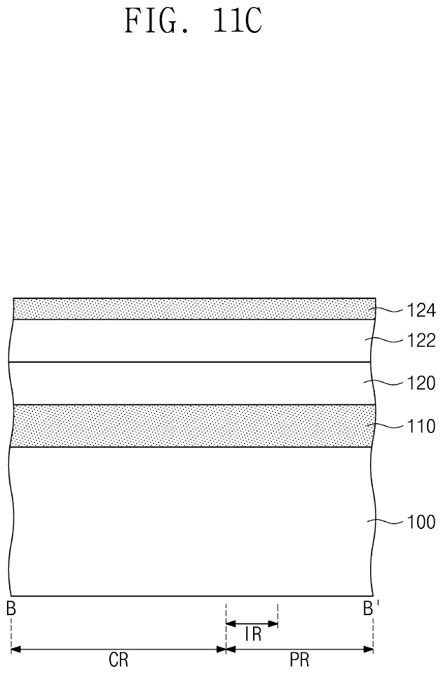

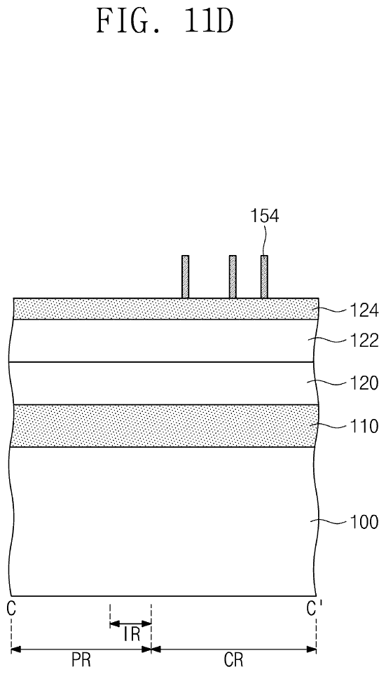

Referring to FIGS. 11A, 11B, 11C, and 11D, the first mask pattern 125 may be removed. For example, an ashing or strip process may be performed to remove the first mask pattern 125.

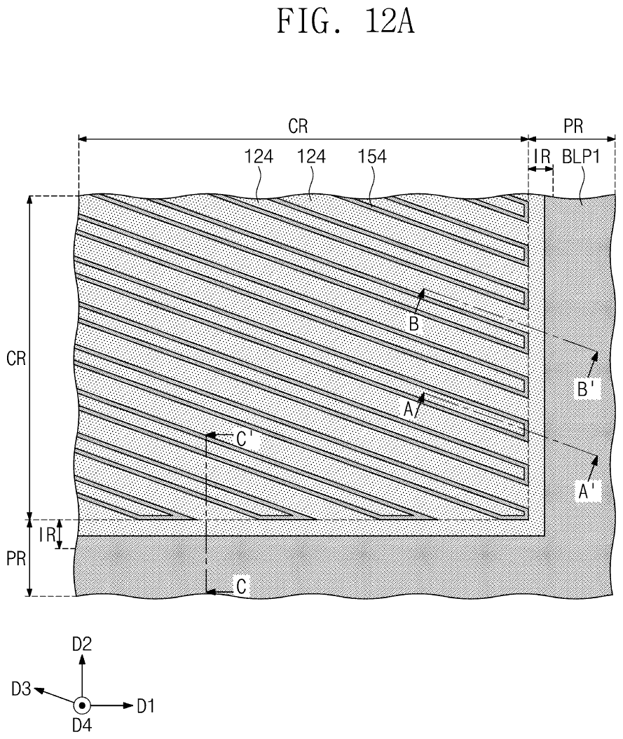

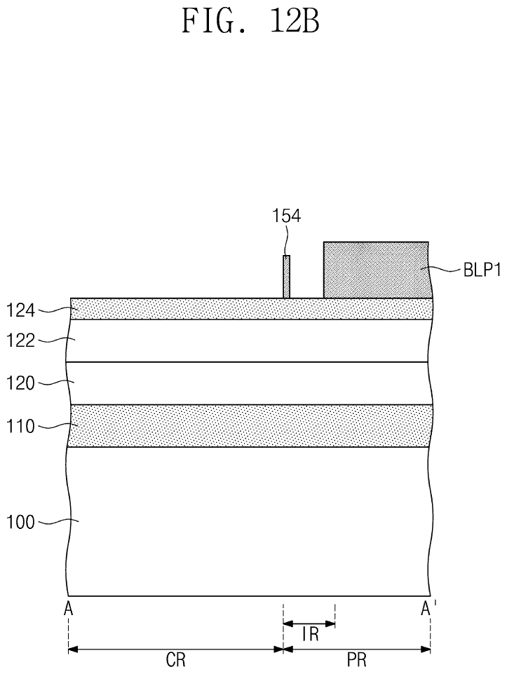

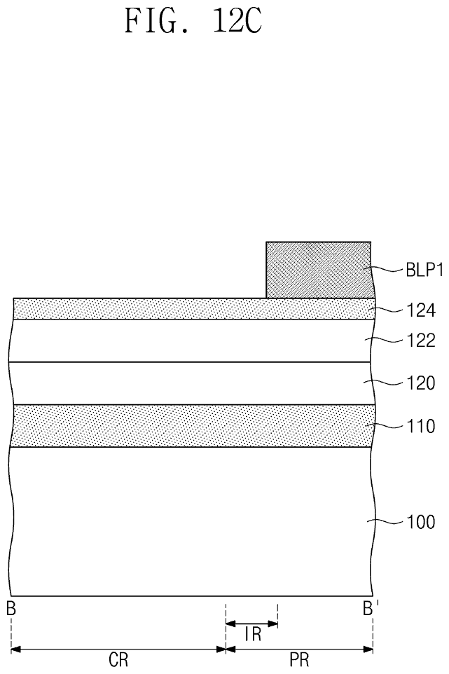

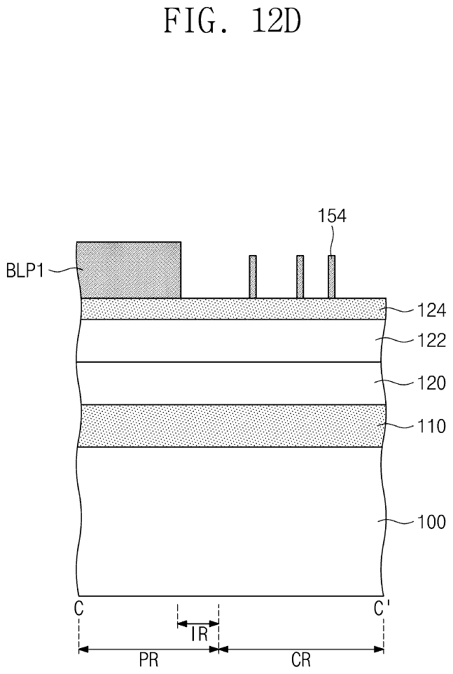

Referring to FIGS. 12A, 12B, 12C, and 12D, a second block pattern BLP1 may be formed on the upper surface of the first etch stop layer 124. For example, a resist layer may be formed on the first etch stop layer 124, and then a portion of the resist layer positioned on the cell region CR may be removed to form the second block pattern BLP1. The second block pattern BLP1 may include a different material from that of the third mask pattern 154. The second block pattern BLP1 may include a photosensitive material, such as a photoresist material. The second block pattern BLP1 may be on (e.g., cover or overlap in the fourth direction D4) the peripheral circuit region PR. On the peripheral circuit region PR, the second block pattern BLP1 may define a zone for forming a peripheral circuit to drive the memory cells (on the cell region CR).

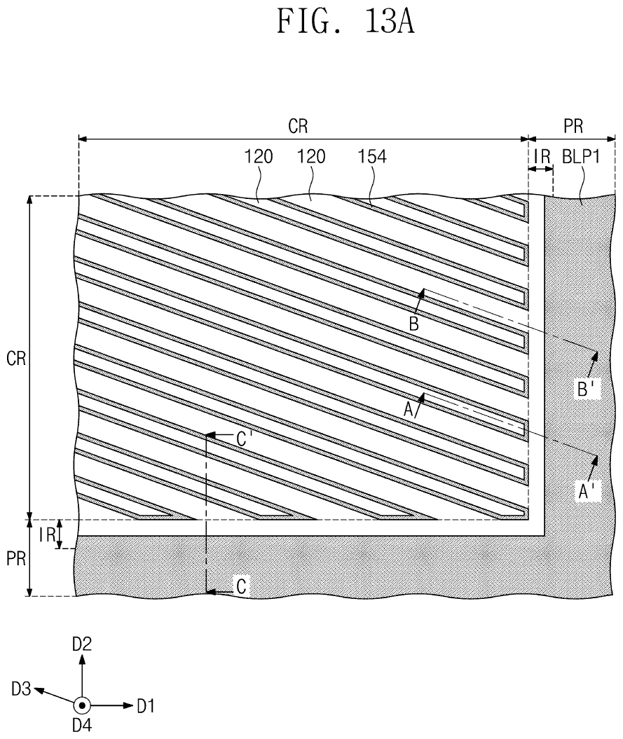

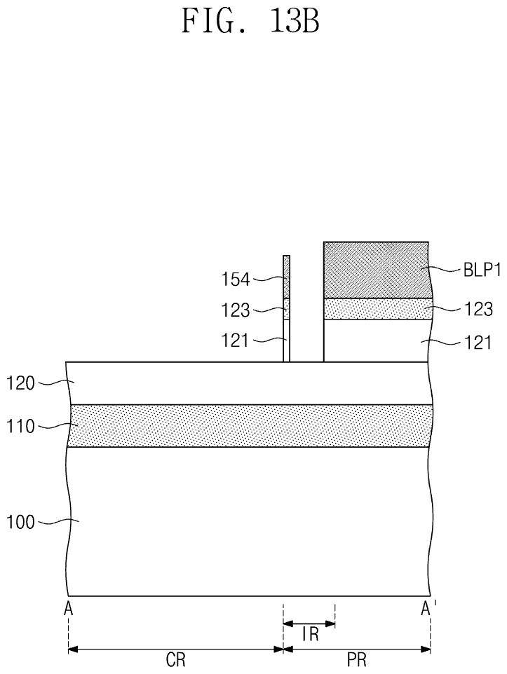

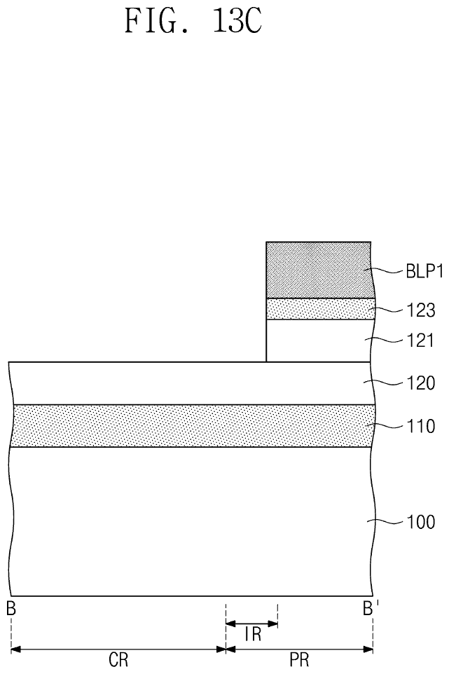

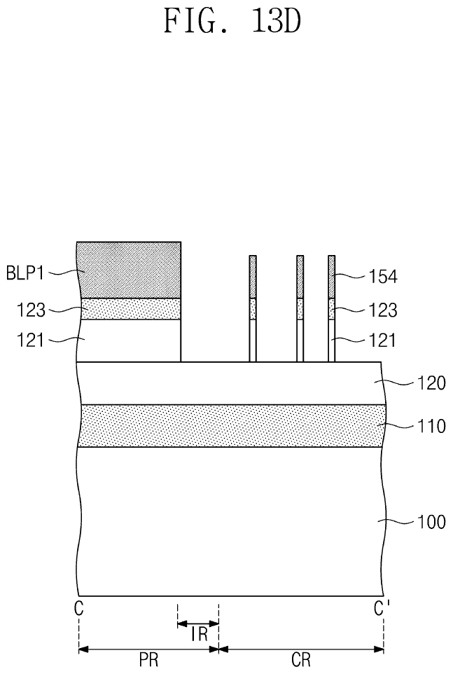

Referring to FIGS. 13A, 13B, 13C, and 13D, the third mask pattern 154 and the second block pattern BLP1 may be used as an etch mask to etch the first etch stop layer 124 and the first mask layer 122. Thus, an active mask pattern 121 and an etch stop pattern 123 may be (sequentially) formed on the semiconductor layer 120. An anisotropic etching process may be employed to etch the first etch stop layer 124 and the first mask layer 122 by using the third mask pattern 154 and the second block pattern BLP1.

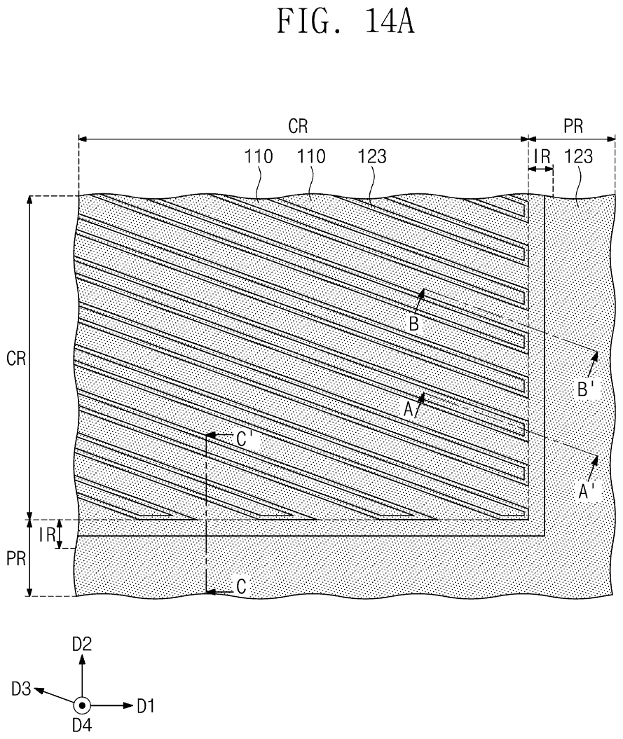

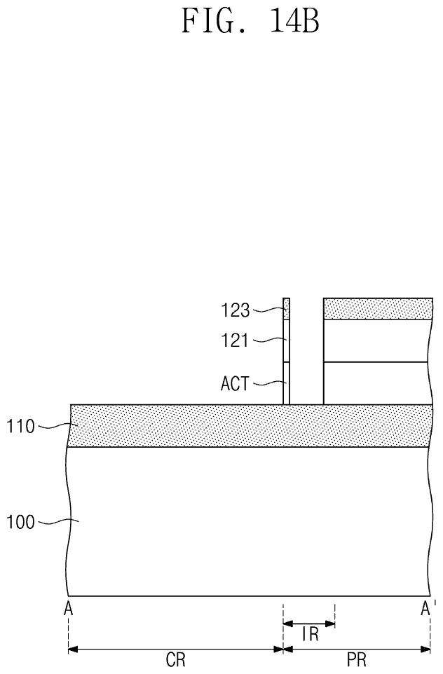

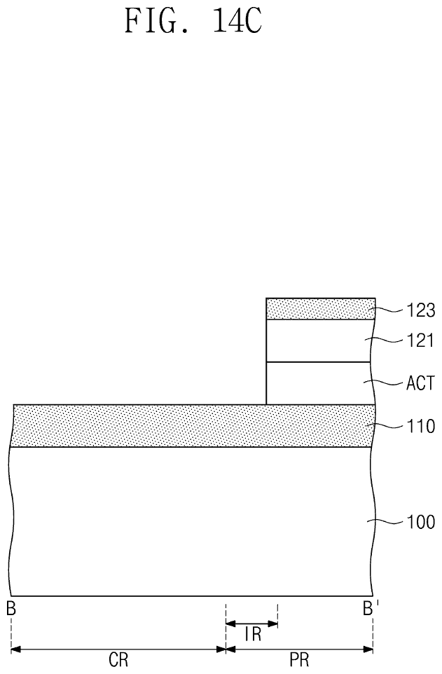

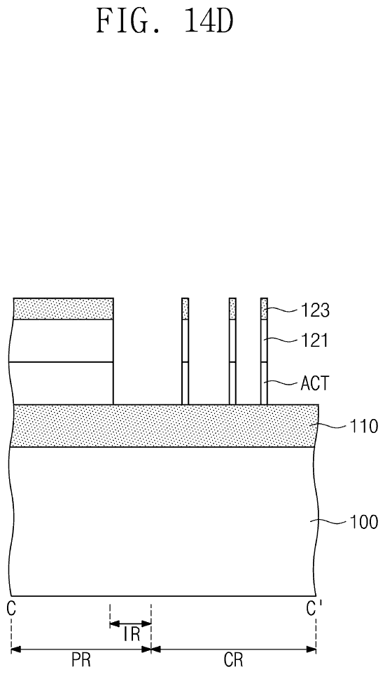

Referring to FIGS. 14A, 14B, 14C, and 14D, the third mask pattern 154 and the second block pattern BLP1 may be removed.

The active mask pattern 121 and the etch stop pattern 123 may be used as an etch mask to etch the semiconductor layer 120. The semiconductor layer 120 may be etched to form active patterns ACT. The active patterns ACT may include line-shaped patterns positioned on the cell region CR and a block-shaped pattern positioned on the peripheral circuit region PR.

Afterwards, the active mask pattern 121 and the etch stop pattern 123 may be removed.

Although not shown, on the cell region CR, the active patterns ACT may be partially patterned to form cell sections for forming semiconductor devices. For example, on the cell region CR, the cell sections may be formed by providing on the active patterns ACT an etch mask (not shown) having openings (not shown) and using the openings to remove portions of the active patterns ACT. The cell sections may have a bar shape elongated in the third direction D3.

Thereafter, a space between the active patterns ACT may be filled with a dielectric material to form a device isolation layer on the dielectric layer 110.

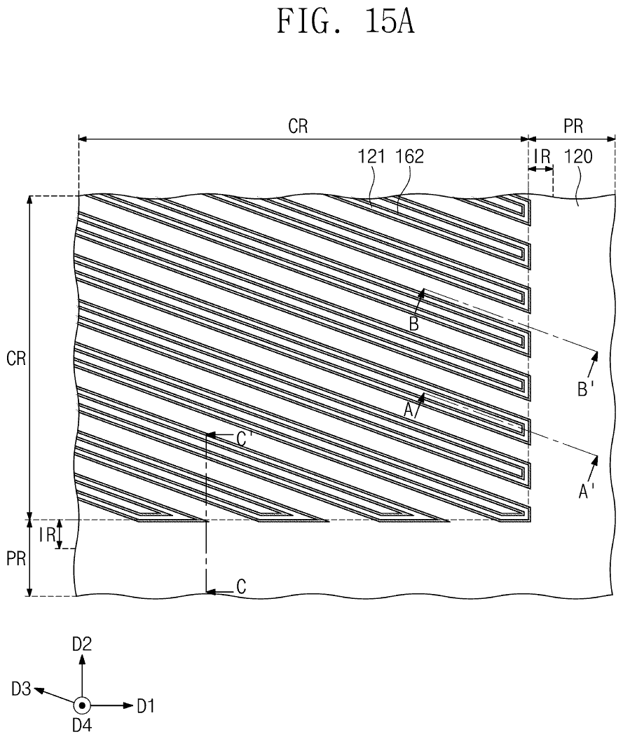

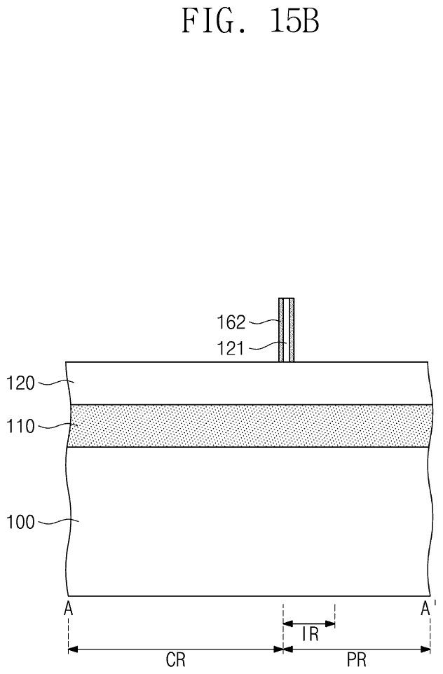

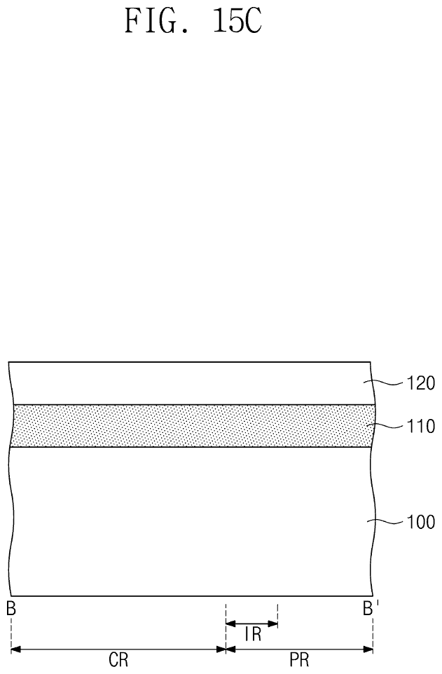

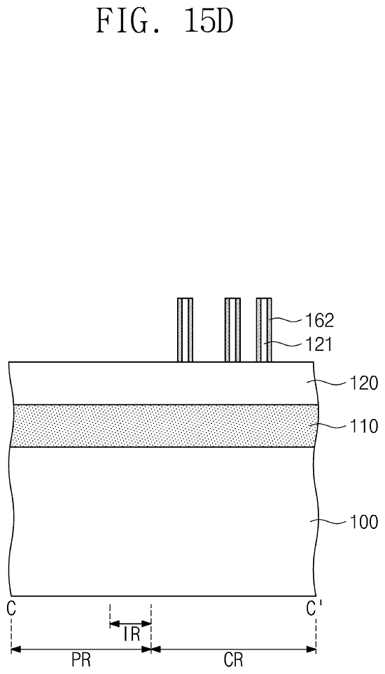

FIGS. 15A, 16A, and 17A illustrate plan views showing a method of fabricating a semiconductor device according to some embodiments of the present inventive concepts. FIGS. 15B, 16B, and 17B illustrate cross-sectional views taken along line A-A′ of FIGS. 15A, 16A, and 17A, respectively. FIGS. 15C, 16C, and 17C illustrate cross-sectional views taken along line B-B′ of FIGS. 15A, 16A, and 17A, respectively. FIGS. 15D, 16D, and 17D illustrate cross-sectional views taken along line C-C′ of FIGS. 15A, 16A, and 17A, respectively.

Referring to FIGS. 15A, 15B, 15C, and 15D, on a resultant structure of FIGS. 13A, 13B, 13C, and 13D, the third mask pattern 154 and the second block pattern BLP1 may be removed. After that, the etch stop pattern 123 may be removed. The active mask pattern 121 on the peripheral circuit region PR may be removed. The active mask pattern 121 on the cell region CR may remain on the semiconductor layer 120.

A fourth mask pattern 162 may be formed on the semiconductor layer 120. The fourth mask pattern 162 may be formed on sidewalls of the active mask pattern 121. For example, a third spacer layer may be formed on the semiconductor layer 120. The third spacer layer may be on (e.g., uniformly cover) an upper surface of the active mask pattern 121, the sidewalls of the active mask pattern 121, and an upper surface of the semiconductor layer 120 exposed by the active mask pattern 121. The third spacer layer may be formed by using, for example, atomic layer deposition (ALD). The third spacer layer may include, for example, a silicon oxide (SiOx) layer and/or a silicon nitride (SiN) layer. An etching process may be performed to etch a portion of the third spacer layer that is on (e.g., covers or overlaps in the fourth direction D4) the upper surface of the semiconductor layer 120 and the upper surface of the active mask pattern 121, thereby forming the fourth mask pattern 162. The fourth mask pattern 162 may be a mask pattern for forming an active pattern on the semiconductor layer 120 in a subsequent process. The etching process may continue until the upper surface of the semiconductor layer 120 is exposed and the upper surface of the active mask pattern 121 is exposed. The fourth mask pattern 162 may be formed on the cell region CR and may not be formed on the peripheral circuit region PR.

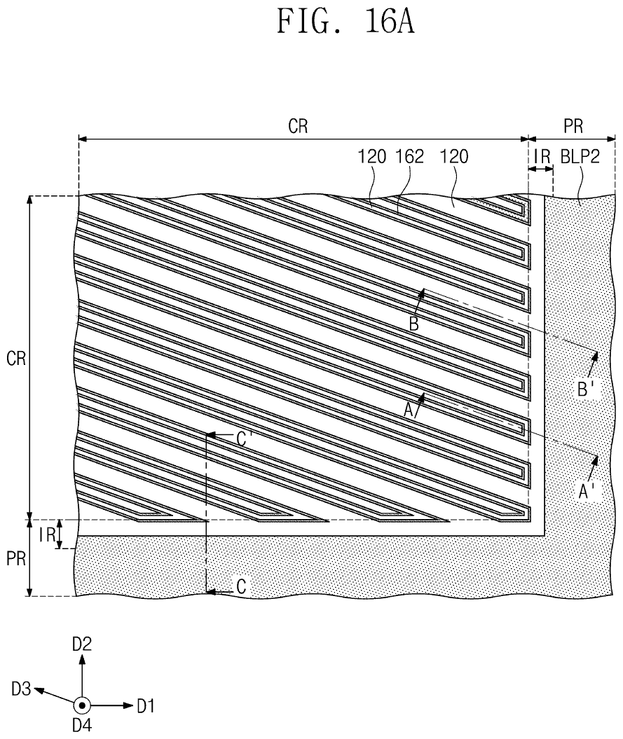

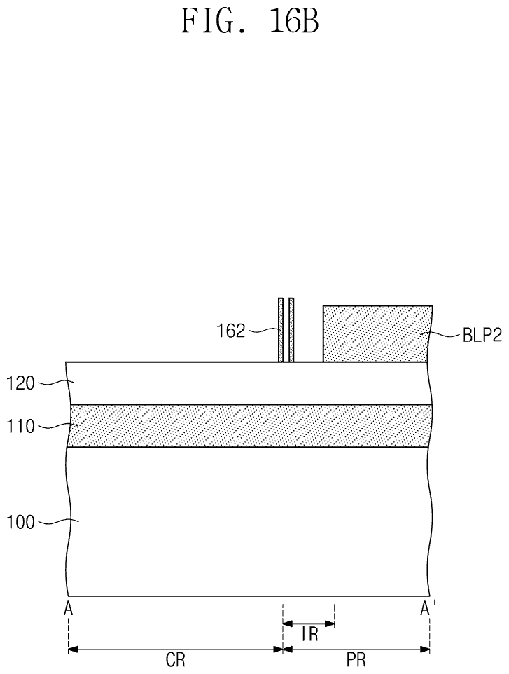

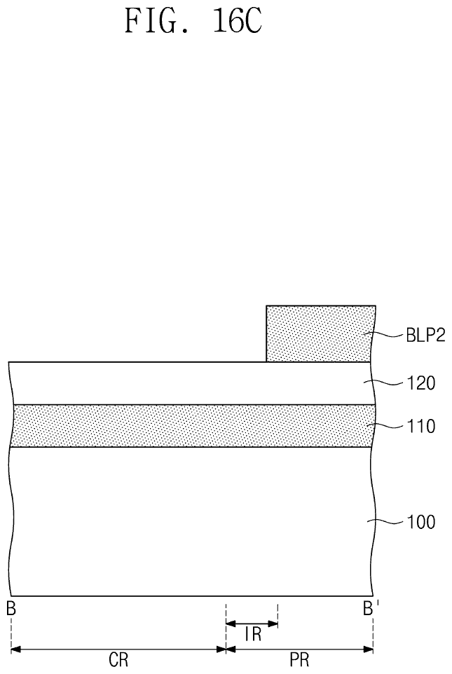

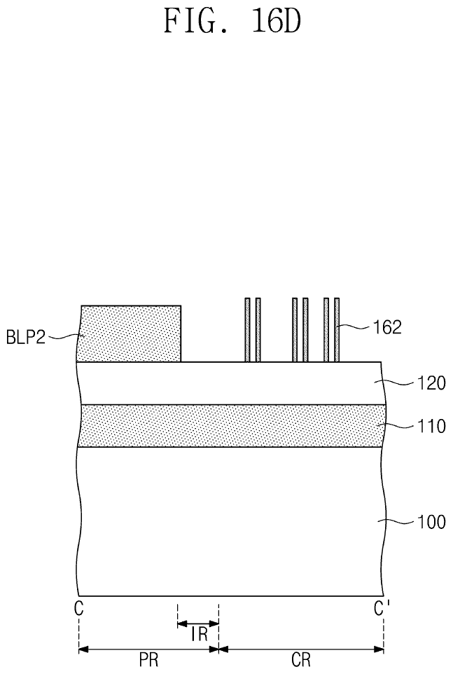

Referring to FIGS. 16A, 16B, 16C, and 16D, the active mask pattern 121 may be removed. For example, an ashing or strip process may be performed to remove the active mask pattern 121.

Then, a third block pattern BLP2 may be formed on the upper surface of the semiconductor layer 120. For example, a resist layer may be formed on the semiconductor layer 120, and then a portion of the resist layer positioned on the cell region CR may be removed to form the third block pattern BLP2. The third block pattern BLP2 may include a different material from that of the fourth mask pattern 162. The third block pattern BLP2 may include a photosensitive material, such as a photoresist material. The third block pattern BLP2 may be on (e.g., cover or overlap in the fourth direction D4) the peripheral circuit region PR. On the peripheral circuit region PR, the third block pattern BLP2 may define a zone for forming a peripheral circuit to drive the memory cells.

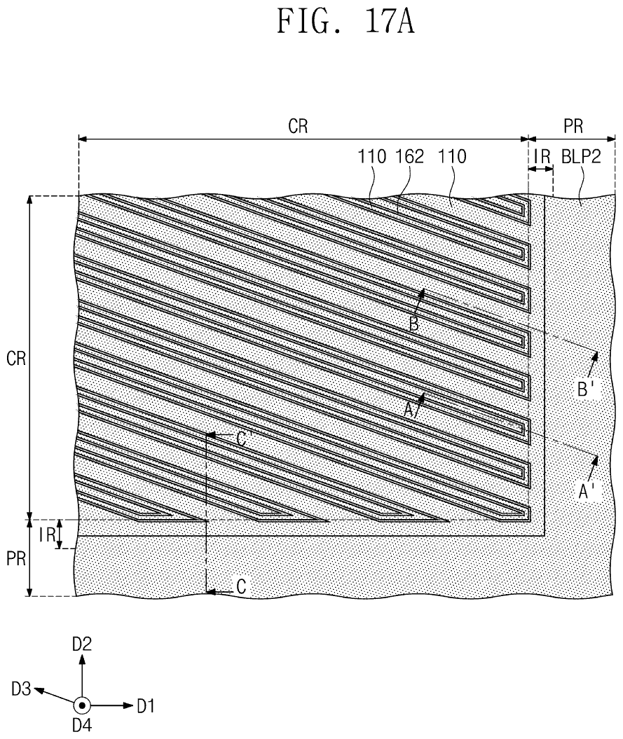

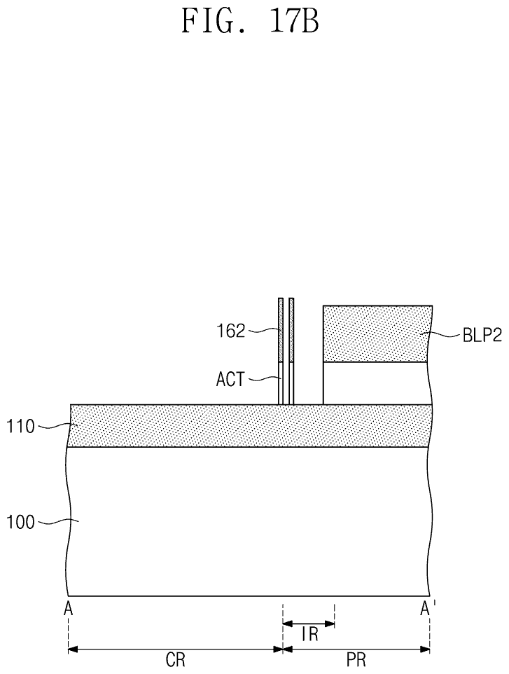

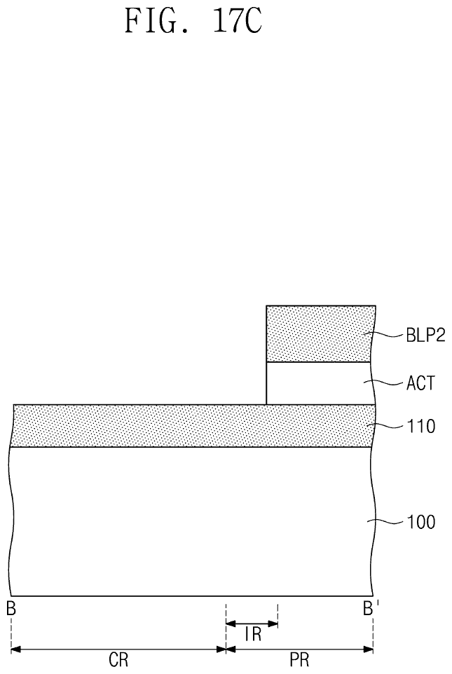

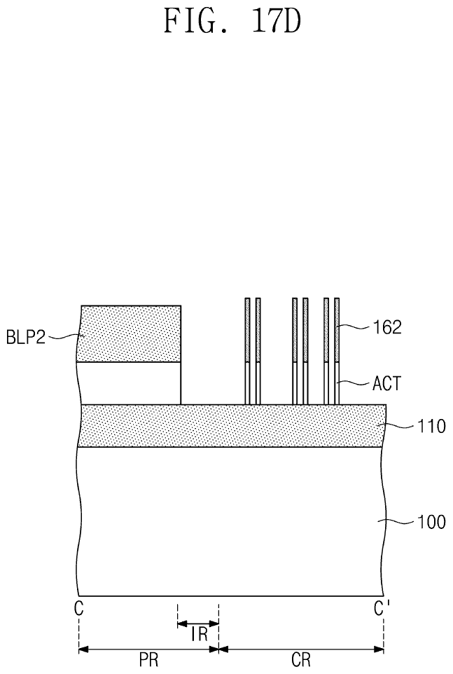

Referring to FIGS. 17A, 17B, 17C, and 17D, the fourth mask pattern 162 and the third block pattern BLP2 may be used as an etch mask to etch the semiconductor layer 120. The semiconductor layer 120 may be etched to form active patterns ACT. The active patterns ACT may include line-shaped patterns positioned on the cell region CR and a block-shaped pattern positioned on the peripheral circuit region PR.

Then, the fourth mask pattern 162 and the third block pattern BLP2 may be removed (not shown).

Although not shown, on the cell region CR, the active patterns ACT may be partially patterned to form cell sections for forming semiconductor devices. For example, on the cell region CR, the cell sections may be formed by providing on the active patterns ACT an etch mask (not shown) having openings (not shown) and using the openings to remove portions of the active patterns ACT. A space between the active patterns ACT may be filled with a dielectric material to form a device isolation layer on the dielectric layer 110.

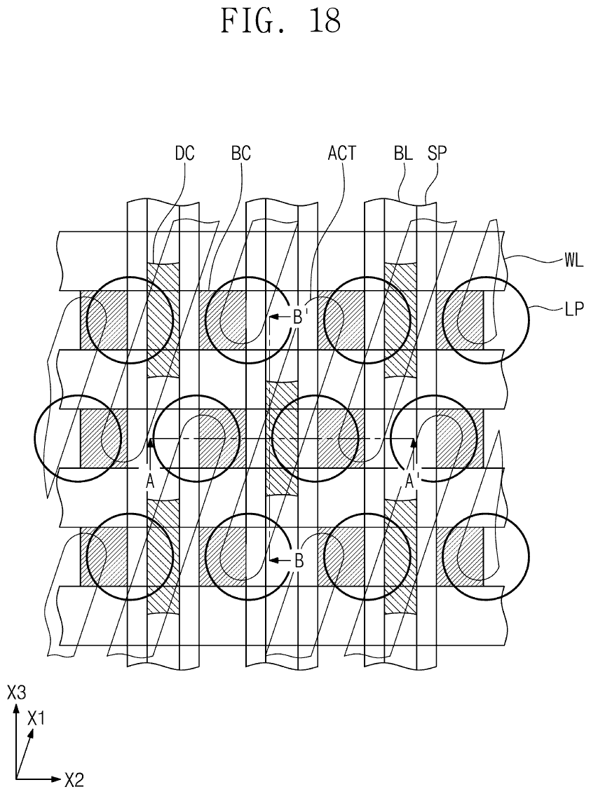

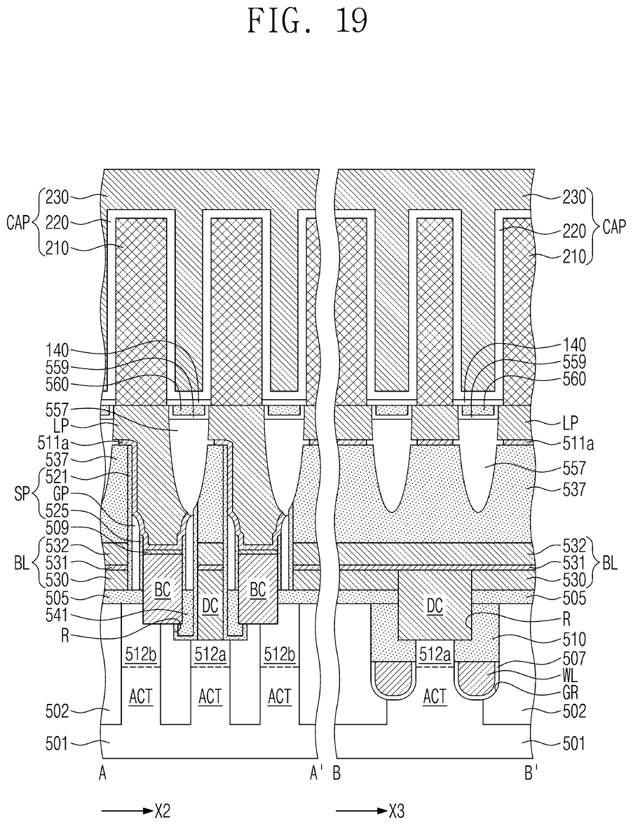

FIG. 18 illustrates a plan view showing a semiconductor device according to some embodiments of the present inventive concepts. FIG. 19 illustrates a cross-sectional view showing a semiconductor device according to some embodiments of the present inventive concepts.

Referring to FIGS. 18 and 19, a substrate 501 may be provided therein with device isolation patterns 502 that define active patterns ACT. Each of the active patterns ACT may have an isolated shape (may be spaced apart from each other). When viewed in plan, each of the active patterns ACT may have a bar shape elongated in a first direction X1. When viewed in plan, the active patterns ACT may correspond to portions of the substrate 501 that are surrounded by the device isolation patterns 502. The substrate 501 may include a semiconductor material. The active patterns ACT may be arranged in parallel to each other such that one of the active patterns ACT may have an end portion adjacent to a central portion of a neighboring one of the active patterns ACT.

Word lines WL may run across (may overlap in a vertical direction) the active patterns ACT. The word lines WL may be disposed in grooves GR formed in the device isolation patterns 502 and the active patterns ACT. The word lines WL may be parallel to a second direction X2 that intersects the first direction X1. The word lines WL may include (e.g., may be formed of) a conductive material. A gate dielectric layer 507 may be disposed between each of the word lines WL and an inner surface of respective groove GR. Although not shown, the grooves GR may have lower surfaces located relatively deeper (e.g., closer to a lower surface of the substrate 501 in the vertical direction) in the device isolation patterns 502 and relatively shallower (e.g., farther from the lower surface of the substrate 501 in the vertical direction) in the active patterns ACT. The gate dielectric layer 507 may include, for example, thermal oxide, silicon nitride (SiN), silicon oxynitride (SiON), and/or high-k dielectric. Each of the word lines WL may have a curved lower surface.

A first impurity region 512a may be disposed in the active pattern ACT between a pair of (adjacent) word lines WL, and a pair of second impurity regions 512b may be disposed in opposite edge portions of the active pattern ACT. The first and second impurity regions 512a and 512b may be doped with, for example, N-type impurities. The first impurity region 512a may correspond to a common drain region, and the second impurity regions 512b may correspond to source regions. A transistor may be constituted by one of the word lines WL and its adjacent first and second impurity regions 512a and 512b. As the word lines WL are disposed in the grooves GR, each of the word lines WL may have thereunder a channel region whose channel length becomes increased within a limited planar area. Accordingly, a short-channel effect may be minimized.

The word lines WL may have their upper surfaces lower than those of the active patterns ACT. A word-line capping pattern 510 may be disposed on each word line WL. The word-line capping patterns 510 may have their linear shapes that extend along longitudinal directions of the word lines WL and may cover (or overlap in the vertical direction) entire upper surfaces of the word lines WL. The grooves GR may have inner spaces not occupied by the word lines WL, and the word-line capping patterns 510 may fill the unoccupied inner spaces of the grooves GR. The word-line capping pattern 510 may include (e.g., may be formed of), for example, a silicon nitride (SiN) layer.

An interlayer dielectric pattern 505 may be disposed on the substrate 501. The interlayer dielectric pattern 505 may include, for example, a silicon oxide (SiO) layer, a silicon nitride (SiN) layer, a silicon oxynitride (SiON) layer, and/or a multiple layer thereof. The interlayer dielectric pattern 505 may be formed to have island shapes that are spaced apart from each other when viewed in plan. The interlayer dielectric pattern 505 may be formed to (simultaneously) cover ends of two adjacent active patterns ACT.

The substrate 501, the device isolation pattern 502, and an upper portion of the word-line capping pattern 510 may be at least partially recessed to form a recess R. The recess R may constitute a net shape when viewed in plan. A sidewall of the recess R may be aligned with that of the interlayer dielectric pattern 505.

Bit lines BL may be disposed on the interlayer dielectric pattern 505. The bit lines BL may run across (or overlap in the vertical direction) the word-line capping patterns 510 and the word lines WL. As disclosed in FIG. 18, the bit lines BL may extend in a third direction X3 that intersects the first and second directions X1 and X2. The first, second, and third directions X1, X2, and X3 are parallel with an upper surface and/or a lower surface of the substrate 501. The vertical direction is perpendicular to the upper surface and/or the lower surface of the substrate 501. The bit lines BL may each include a bit-line polysilicon pattern 530, a bit-line ohmic pattern 531, and a bit-line metal-containing pattern 532 that are sequentially stacked. The bit-line polysilicon pattern 530 may include, for example, impurity-doped polysilicon and/or impurity-undoped polysilicon. The bit-line ohmic pattern 531 may include, for example, a metal silicide layer. The bit-line metal-containing pattern 532 may include, for example, metal (e.g., tungsten (W), titanium (Ti), and/or tantalum (Ta)) and/or conductive metal nitride (e.g., titanium nitride (TiN), tantalum nitride (TaN), and/or tungsten nitride (WN)). A bit-line capping pattern 537 may be disposed on each of the bit lines BL. The bit-line capping pattern 537 may include (e.g., may be formed of) a dielectric material, such as a silicon nitride (SiN) layer.

Bit-line contacts DC may be disposed in the recess R that intersects (or overlaps in the vertical direction) the bit lines BL. The bit-line contacts DC may include, for example, impurity-doped polysilicon and/or impurity-undoped polysilicon. When viewed in cross-section taken along line B-B′ as shown in FIG. 19, the bit-line contact DC may have a sidewall in contact with that of the interlayer dielectric pattern 505. When viewed in plan as shown in FIG. 18, the bit-line contact DC may have a concave lateral surface (that is concave toward to a central portion of the bit-line contact DC) in contact with the interlayer dielectric pattern 505. The bit-line contact DC may electrically connect the first impurity region 512a to the bit line BL.

The recess R may have an empty space not occupied by the bit-line contact DC, and a lower buried dielectric pattern 541 may be disposed in the empty space of the recess R. The lower buried dielectric pattern 541 may include (e.g., may be formed of) a silicon oxide (SiO) layer, a silicon nitride (SiN) layer, a silicon oxynitride (SiON) layer, and/or a multiple layer thereof.

Storage node contacts BC may be disposed between a pair of neighboring bit lines BL. The storage node contacts BC may be spaced apart from each other. The storage node contacts BC may include, for example, impurity-doped polysilicon and/or impurity-undoped polysilicon. The storage node contacts BC may have their concave upper surfaces. A dielectric pattern (not shown) may be disposed between the storage node contacts BC and between the bit lines BL.

A bit-line spacer SP may be interposed between the bit line BL and the storage node contact BC. The bit-line spacer SP may include a first spacer 521 and a second spacer 525 that are spaced apart from each other across (by) a gap GP. The gap GP may refer to an air gap. The first spacer 521 may be on (e.g., may cover) a sidewall of the bit line BL and a sidewall of the bit-line capping pattern 537. The second spacer 525 may be adjacent to (may be on a sidewall of) the storage node contact BC. The first spacer 521 and the second spacer 525 may include the same material. For example, the first spacer 521 and the second spacer 525 may include a silicon nitride (SiN) layer.

The second spacer 525 may have a lower surface lower than that of the first spacer 521. The second spacer 525 may have an upper end whose height (level) is lower than that of an upper end of the first spacer 521. Such a configuration may increase a formation margin for landing pads LP which will be discussed below. As a result, no connection (e.g., disconnection or separation) may be prevented between the landing pad LP and the storage node contact BC. The first spacer 521 may extend to be on (to cover) the sidewall of the bit-line contact DC and a sidewall and a lower surface of the recess R. For example, the first spacer 521 may be interposed between the bit-line contact DC and the lower buried dielectric pattern 541, between the word-line capping pattern 510 and the lower buried dielectric pattern 541, between the substrate 501 and the lower buried dielectric pattern 541, and between the device isolation pattern 502 and the lower buried dielectric pattern 541.

A storage node ohmic layer 509 may be disposed on the storage node contact BC. The storage node ohmic layer 509 may include, for example, metal silicide. The storage node ohmic layer 509, the first and second spacers 521 and 525, and the bit-line capping pattern 537 may be covered (overlapped) with a diffusion stop pattern 511a whose thickness is uniform. The diffusion stop pattern 511a may be on the storage node ohmic layer 509, the first and second spacers 521 and 525, and the bit-line capping pattern 537. The diffusion stop pattern 511a may include, for example, metal nitride, such as a titanium nitride (TiN) layer and/or a tantalum nitride (TaN) layer.

A landing pad LP may be disposed on the diffusion stop pattern 511a. The landing pad LP may have an upper portion that is on (e.g., covers or overlap in the vertical direction) an upper surface of the bit-line capping pattern 537 and has a width greater than that of the storage node contact BC. A center of the landing pad LP may be shifted in the second direction X2 away from a center of the storage node contact BC. A portion of the bit line BL may vertically overlap the landing pad LP. An upper sidewall of the bit-line capping pattern 537 may overlap the landing pad LP (in the vertical direction).

A pad isolation pattern 557 may be interposed between the landing pads LP. The pad isolation pattern 557 may include, for example, a silicon nitride (SiN) layer, a silicon oxide (SiO) layer, a silicon oxynitride (SiON) layer, and/or a porous layer. The pad isolation pattern 557 may define an upper end of the gap GP.

On the pad isolation pattern 557, a first capping pattern 559 may be provided between neighboring landing pads LP. The first capping pattern 559 may have a liner shape, and an inside of the first capping pattern 559 may be filled with a second capping pattern 560. The first and second capping patterns 559 and 560 may respectively include, for example, a silicon nitride (SiN) layer, a silicon oxide (SiO) layer, a silicon oxynitride (SiON) layer, and/or a porous layer. The first capping pattern 559 may have porosity greater than that of the second capping pattern 560.

Bottom electrodes 210 may be correspondingly disposed on the landing pads LP. The bottom electrode 210 may be a pillar or cylindrical electrode. The bottom electrodes 210 may include, for example, oxide electrodes. For example, the bottom electrodes 210 may include strontium ruthenate (SrRuO₃) and/or tin oxide (SnO₂) doped with tantalum (Ta). In some embodiments, the bottom electrodes 210 may include metal, metal oxide, and/or doped polysilicon.

The bottom electrodes 210 may be provided therebetween with an etch stop layer 140 that is on (e.g., covers or overlaps in the vertical direction) an upper surface of the pad isolation pattern 557 or upper surfaces of the first and second capping patterns 559 and 560. The etch stop layer 140 may include, for example, a dielectric material, such as a silicon nitride (SiN) layer, a silicon oxide (SiO) layer, and/or a silicon oxynitride (SiON) layer. The bottom electrodes 210 may have their surfaces covered with a dielectric layer 220. For example, the dielectric layer 220 may be on the sidewalls and an upper surface of the bottom electrode 210. The dielectric layer 220 may be covered with a top electrode 230. The top electrode 230 may be on the dielectric layer 220.

In a method of fabricating a semiconductor device according to some embodiments of the present inventive concepts, line patterns may be formed from a cell region onto a peripheral circuit region, and thus the cell region may be provided thereon with normally formed portions of the line patterns that completely penetrate a mask layer. For example, no bad pattern may be present on the cell region. Afterwards, a mask pattern positioned on the peripheral circuit region may be removed to eliminate the bad pattern formed on ends or edges of the line patterns, and the normally shaped line patterns may be formed on the cell region. There may thus be no occurrence of failure caused by insufficient exposure of a pattern on the cell region. As a result, there may be provided a method of fabricating a semiconductor device with less occurrence of failure.

Herein, chemical symbols should be considered illustrative and not restrictive. For example, SiO may also refer to SiO₂ or the like.

Although the present invention has been described in connection with some embodiments of the present inventive concepts illustrated in the accompanying drawings, it will be understood by one of ordinary skill in the art that variations in form and detail may be made therein without departing from the scope of the present inventive concepts. The above disclosed embodiments should thus be considered illustrative and not restrictive.

What is claimed is:

1. A method of fabricating a semiconductor device, the method comprising:
providing a substrate that includes a cell region and a peripheral circuit region;
sequentially stacking a first mask layer and a second mask layer on the substrate;
patterning the second mask layer to form a first mask pattern that includes line patterns, wherein the first mask pattern includes a first portion on the cell region and a second portion on the peripheral circuit region,
wherein each of the line patterns extends across the cell region in a horizontal direction that is parallel with an upper surface and/or a lower surface of the substrate,
wherein each of the line patterns extends in the horizontal direction into a portion of the peripheral circuit region, and
wherein the portion of the peripheral circuit region is adjacent the cell region;
removing the second portion of the first mask pattern;
forming a first spacer layer on an upper surface of the first mask layer and on sidewalls and an upper surface of the first portion of the first mask pattern;
etching the first spacer layer by a first anisotropic etching process to form second mask patterns on the sidewalls of the first portion of the first mask pattern;
removing the first portion of the first mask pattern;
forming a third mask pattern on the peripheral circuit region; and
patterning the first mask layer using the second mask patterns and the third mask pattern.

2. The method of claim 1, wherein the second portion of the first mask pattern includes a block pattern that is spaced apart from the line patterns.

3. The method of claim 1, further comprising:
forming a second spacer layer on the first mask pattern before the removing the second portion of the first mask pattern;
forming a photomask pattern on the second spacer layer on the cell region;
etching a portion of the second spacer layer by a second anisotropic etching process to expose an upper surface of the second portion of the first mask pattern;
removing the photomask pattern; and
removing the second spacer layer after the removing the second portion of the first mask pattern.

4. The method of claim 1, wherein the second portion of the first mask pattern includes end portions of the line patterns.

5. The method of claim 1, wherein the third mask pattern includes a first material that is different from a second material included in the second mask patterns.

6. The method of claim 5, wherein the first material includes a photosensitive material.

7. The method of claim 1, wherein during the etching the first spacer layer,
the first spacer layer is removed from the peripheral circuit region, and
an upper portion of the first mask layer is partially removed from the peripheral circuit region.

8. The method of claim 1, wherein the portion of the peripheral circuit region extends around the cell region in a plan view, and
wherein the second portion of the first mask pattern is disposed on the portion of the peripheral circuit region.

9. The method of claim 1, wherein a width of each of the line patterns and an interval between adjacent line patterns among the line patterns are in a range of 2 nanometers to 10 nanometers.

10. The method of claim 1, wherein the first mask layer includes a silicon carbonitride (SiCN) layer and/or a silicon oxynitride (SiON) layer, and
wherein the second mask layer includes a spin-on-hardmask (SOH) layer.

11. A method of fabricating a semiconductor device, the method comprising:
providing a substrate that includes a cell region and a peripheral circuit region;
sequentially stacking a first mask layer and a second mask layer on the substrate;
patterning the second mask layer to form a first mask pattern, wherein the first mask pattern includes a first portion on the cell region and a second portion on the peripheral circuit region;
removing the second portion of the first mask pattern;
forming second mask patterns on sidewalls of the first portion of the first mask pattern;
removing the first portion of the first mask pattern;
forming a third mask pattern on the peripheral circuit region; and
patterning the first mask layer using the second mask patterns and the third mask pattern,
wherein the third mask pattern includes a first material different from a second material of the first mask pattern.

12. The method of claim 11 further comprising:
forming a first spacer layer on the first mask pattern before the removing the second portion of the first mask pattern;
forming a photomask pattern on the first spacer layer on the cell region;
etching a portion of the first mask layer by an anisotropic etching process to expose an upper surface of the second portion of the first mask pattern;
removing the photomask pattern; and
removing the first spacer layer after the removing the second portion of the first mask pattern.

13. The method of claim 11, wherein the first mask pattern includes line patterns that extend in a horizontal direction that is parallel with an upper surface and/or a lower surface of the substrate, and
wherein the second portion of the first mask pattern includes a block pattern that is spaced apart from the line patterns.

14. The method of claim 13, wherein each of the line patterns extends in the horizontal direction on the cell region, and
wherein each of the line patterns extends in the horizontal direction on a portion of the peripheral circuit region.

15. The method of claim 14, wherein the second portion of the first mask pattern includes end portions of the line patterns.

16. The method of claim 13, wherein a width of each of the line patterns and an interval between adjacent line patterns among the line patterns are in a range of 2 nanometers to 10 nanometers.

17. The method of claim 11, wherein forming the second mask patterns on the sidewalls of the first portion of the first mask pattern includes:
forming a second spacer layer on an upper surface of the first mask layer and on the sidewalls and an upper surface of the first portion of the first mask pattern; and
etching the second spacer layer by an anisotropic etching process.

18. The method of claim 17, wherein during the etching the second spacer layer,
the second spacer layer is removed from the peripheral circuit region, and
an upper portion of the first mask layer is partially removed from the peripheral circuit region.

19. The method of claim 11, wherein the third mask pattern includes a photosensitive material.

20. A method of fabricating a semiconductor device, the method comprising:
providing a substrate that includes a cell region and a peripheral circuit region;
sequentially stacking a first mask layer and a second mask layer on the substrate;
patterning the second mask layer to form a first mask pattern that includes line patterns on the cell region and a block pattern on the peripheral circuit region, wherein the line patterns extend from the cell region onto the peripheral circuit region,
wherein lower surfaces of the line patterns on the cell region exposes the first mask layer, and
wherein lower surfaces of the line patterns on the peripheral circuit region exposes the second mask layer;
forming a spacer layer on the first mask pattern;
etching the spacer layer on the peripheral circuit region by an anisotropic etching process to expose an upper surface of the block pattern and an upper surface of a first portion of the line patterns on the peripheral circuit region;
removing the first portion of the line patterns on the peripheral circuit region and the block pattern;
removing the spacer layer;
forming a plurality of second mask patterns on sidewalls of a second portion of the line patterns on the cell region;
removing the second portion of the line patterns;
forming a third mask pattern on the peripheral circuit region; and
patterning the first mask layer using the second mask patterns and the third mask pattern.
